(19) United States
(12) Patent Application Publication
(10) Pub. No.: US 2024/0420025 A1
(43) Pub. Date: Dec. 19, 2024

(54) GENERATING AUGMENTED DATA TO TRAIN MACHINE LEARNING MODELS TO PRESERVE PHYSICAL TRENDS

(71) Applicant: ASML NETHERLANDS B.V., Veldhoven (NL)

(72) Inventors: Jiaxing REN, Sunnyvale, CA (US); Yongfa FAN, Cupertino, CA (US); Yi-Yin CHEN, Santa Clara, CA (US); Chenji ZHANG, San Jose, CA (US); Leiwu ZHENG, San Jose, CA (US)

(73) Assignee: ASML NETHERLANDS B.V., Veldhoven (NL)

(21) Appl. No.: 18/703,486

(22) PCT Filed: Nov. 12, 2022
(86) PCT No.: PCT/EP2022/081686

§ 371 Date: Apr. 22, 2024

Related U.S. Application Data
(60) Provisional application No. 63/279,263, filed on Nov. 15, 2021.
(60) Provisional application No. 63/420,044, filed on Oct. 27, 2022.

(51) Int. Cl. G06N 20/00; G03F 7/00

(52) U.S. Cl. CPC G06N 20/00; G03F 7/705; G03F 7/706841

(57) ABSTRACT

Machine learning models can be trained to predict imaging characteristics with respect to variation in a pattern on a wafer resulting from a patterning process. However, due to low pattern coverage provided by limited wafer data used for training, machine learning models tend to overfit, and predictions from the machine learning models deviate from physical trends that characterize the pattern on the wafer and/or the patterning process with respect to the pattern variation. To enhance pattern coverage, training data is augmented with pattern data that conforms to a certain expected physical trend, and applies to new patterns not covered by previously measured wafer data.

### CROSS-REFERENCE TO RELATED APPLICATIONS

This application claims priority of U.S. application 63/279,263 which was filed on Nov. 15, 2021 and U.S. application 63/420,044 which was filed on Oct. 27, 2022 which are incorporated herein in its entirety by reference.

### TECHNICAL FIELD

The present disclosure relates generally to machine learning models associated with computational lithography.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced. At the same time, the number of functional elements, such as transistors, per device has been steadily increasing, following a trend commonly referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k1 lithography, according to the resolution formula CD=k1×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, source mask optimization (SMO), or other methods generally defined as “resolution enhancement techniques” (RET).

### SUMMARY

Machine learning models can be trained to predict imaging characteristics with respect to variation in a pattern on a wafer resulting from a patterning process. However, due to low pattern coverage provided by limited wafer data used for training, machine learning models tend to overfit, and predictions from the machine learning models deviate from physical trends that characterize the patterning process with respect to the pattern variation. According to embodiments of the present disclosure, to enhance pattern coverage, training data is augmented with pattern data that conforms to a certain expected physical trend, and applies to new patterns not covered by previously measured wafer data.

According to an embodiment, there is provided a non-transitory computer readable medium having instructions thereon, the instructions when executed by a computer causing the computer to perform a method. The method comprises obtaining or otherwise determining a physical trend of one or more imaging characteristics with respect to pattern variation on a substrate resulting from a patterning process. In some embodiments, the physical trend is associated with pattern design variation and/or patterning process variation. The physical trend is obtained or determined based on first data for a first set of patterns and/or the patterning process. In some embodiments, the first data comprises previously determined measurements of the pattern on the substrate, and/or information indicative of a physical behavior of the pattern on the substrate resulting from the patterning process. The method comprises generating augmented data based on the physical trend. The augmented data is new relative to the previously determined measurements and/or the information indicative of the physical behavior of the pattern on the substrate, but still conforms to the physical trend. The augmented data comprises second data that conforms to the physical trend and is derived based on the first data. The augmented data is derived for a second set of patterns that are different from the first set. The augmented data is configured to be provided as input to a machine learning model to train the machine learning model to predict the one or more imaging characteristics according to the physical trend.

In some embodiments, the augmented data is provided as input to the machine learning model to train the machine learning model to conform predictions of the one or more imaging characteristics according to the physical trend.

In some embodiments, the method further comprises providing the augmented data to the machine learning model to train the machine learning model to predict the one or more imaging characteristics according to the physical trend.

In some embodiments, the one or more imaging characteristics comprise a critical dimension, an edge location, a curvature, a pitch, a symmetry, or a rotation.

In some embodiments, the patterning process comprises a lithography process and/or an etching process.

In some embodiments, generating the augmented data is based on measurements of the one or more imaging characteristics included in the first data. The first data comprises previously determined data for the first set of patterns and/or the patterning process that at least partially defines the physical trend.

In some embodiments, generating the augmented data comprises mathematically interpolating between the measurements of a given imaging characteristic to determine additional measurements of the given imaging characteristic.

In some embodiments, generating the augmented data comprises calibrating a physical model associated with the physical trend using the measurements, and using the calibrated physical model to predict additional measurements that conform to the physical trend.

In some embodiments, the physical model comprises a multi-dimensional algorithm having terms that collectively simulate the physical trend and/or the patterning process.

In some embodiments, generating the augmented data further comprises calibrating, using the measurements, a residue model configured to compensate for error in the predicted additional measurements, and generating the augmented data using the physical model and the residue model.

The residue model comprises a purely mathematical model calibrated by fitting errors in predictions from the physical model to the measurements.

In some embodiments, generating the augmented data is based on the measurements and symmetry in the pattern resulting from the patterning process.

In some embodiments, generating the augmented data comprises determining the physical trend based on outputs from a calibrated physical model. The trend may be described by relative relationships between values of imaging characteristics predicted by the physical model, rather than absolute values of the imaging characteristics themselves.

In some embodiments, the physical trend comprises a symmetry trend, an orientation trend, a focus trend, a dose trend, a through pitch trend, a linearity trend, and/or a through critical dimension trend.

In some embodiments, the machine learning model is trained to predict the one or more imaging characteristics according to the physical trend based on a loss function configured to cause the machine learning model to fit the relative relationships between values of imaging characteristics predicted by the physical model, rather than the absolute values of the imaging characteristics themselves.

In some embodiments, the physical trend is obtained or otherwise determined based on prior pattern variation on the substrate and/or prior patterning process variation.

In some embodiments, output from the machine learning model is configured to be provided to a cost function to facilitate determination of costs associated with individual patterning process variables.

In some embodiments, the first data comprises previously determined measurements of a first pattern or set of patterns on a first substrate produced by a first patterning process. The physical trend is determined and/or otherwise obtained by (1) extracting and/or categorizing measurements of the first pattern or set of patterns on the first substrate associated with the physical trend, and/or (2) fitting a physical model to the measurements of the first pattern or set of patterns.

In some embodiments, the first patterning process comprises one or more semiconductor manufacturing patterning processes that have similar and comparable process conditions with a second patterning process.

In some embodiments, the second patterning process comprises a target patterning process which is simulated and/or for which a model is constructed.

In some embodiments, the augmented data comprises new data generated based on the physical trend and/or by the physical model, and/or a subset of the previously determined measurements from the first data that conforms to the physical trend.

In some embodiments, the augmented data is combinable with second measurements from a second pattern or set of patterns on a second substrate produced by the second patterning process.

In some embodiments, the subset of the previously determined measurements from the first data that conforms to the physical trend comprises data associated with a previous mask when the first patterning process and the second patterning process are similar.

In some embodiments, the subset of the previously determined measurements from the first data that conforms to the physical trend comprises data associated with different locations on a current mask when the second patterning process is adjusted relative to the first patterning process.

In some embodiments, the second data comprises less second measurements from the second pattern on the second substrate produced by the second patterning process compared to a quantity for the second measurements if no augmented data is used, the less second measurements being combinable with the new data generated based on the physical trend and/or by the physical model, and/or the subset of the previously determined measurements from the first data that conforms to the physical trend.

In some embodiments, a total amount of the augmented data has a same or increased data density relative to the previously determined measurements of the first pattern on the first substrate produced by the first patterning process.

In some embodiments, the augmented data is associated with a normalized standard deviation based loss function.

In some embodiments, the augmented data, the second measurement data, and/or the normalized standard deviation based loss function are used to train the machine learning model.

In some embodiments, the normalized standard deviation based loss function is normalized based on a range of all critical dimensions in the first data associated with the physical trend.

According to another embodiment, there is provided a non-transitory computer readable medium having instructions thereon, the instructions when executed by a computer, causing the computer to train a machine learning model with augmented training data determined based on physical trends associated with a set of patterns on a wafer and/or process variation resulting from a lithography process, the augmented training data configured to enhance a prediction accuracy of a machine learning model with respect to the physical trends relative to prior models. The instructions cause operations comprising: determining a physical trend of one or more imaging characteristics with respect to variation in the set of patterns on the wafer resulting from the lithography process, the physical trend obtained or otherwise determined based on first data for a first set of patterns and/or the lithography process; generating the augmented training data based on the physical trend, the augmented training data comprising second data that conforms to the physical trend and is derived based on the first data, the augmented training data derived for a second set of patterns that are different from the first set; and providing the augmented training data as input to a machine learning model to train the machine learning model to predict the one or more imaging characteristics according to the physical trend.

In some embodiments, the one or more imaging characteristics comprise a critical dimension, an edge location, a curvature, a pitch, a symmetry, or a rotation.

In some embodiments, generating the augmented training data is based on measurements of imaging characteristics included in the first data. In some embodiments, generating the augmented training data comprises mathematically interpolating between the measurements of a given imaging characteristic to determine additional measurements of the given imaging characteristic. In some embodiments, generating the augmented training data comprises calibrating a physical model associated with the physical trend using the measurements, and using the calibrated physical model to predict additional measurements. In some embodiments, generating the augmented training data comprises calibrating, using the measurements, a residue model configured to compensate for error in the predicted additional measurements, and generating the augmented training data using the physical model and the residue model (the residue model comprises a purely mathematical model calibrated by fitting errors in predictions from the physical model to the measurements). In some embodiments, generating the augmented training data is based on the measurements and symmetry in the pattern resulting from the lithography process.

In some embodiments, generating the augmented training data comprises determining the physical trend based on outputs from a trained physical model, the trend described by relative relationships between values of imaging characteristics predicted by the physical model, rather than absolute values of the imaging characteristics themselves.

According to another embodiment, there is provided a method for generating the augmented data comprising one or more of the operations described above.

According to another embodiment, there is provided a system for generating the augmented data. The system comprises one or more hardware processors configured by machine readable instructions to perform one or more of the operations described above.

### BRIEF DESCRIPTION OF THE DRAWINGS

The accompanying drawings, which are incorporated in and constitute a part of the specification, illustrate one or more embodiments and, together with the description, explain these embodiments. Embodiments of the invention will now be described, by way of example only, with reference to the accompanying schematic drawings in which corresponding reference symbols indicate corresponding parts, and in which:

FIG. 1 illustrates a block diagram of various subsystems of a lithographic projection apparatus, according to an embodiment of the present disclosure.

FIG. 2 illustrates a flow chart of an exemplary method for simulating lithography in a lithographic projection apparatus, according to an embodiment of the present disclosure.

FIG. 3 illustrates an exemplary method of generating augmented data, according to an embodiment of the present disclosure.

FIG. 4 illustrates data used to augment training of a machine learning model, according to an embodiment of the present disclosure.

FIG. 5 illustrates generating augmented data by mathematically interpolating between measurements of a given imaging characteristic to determine additional (interpolated) measurement data points (e.g., augmented training data) for the given imaging characteristic, according to an embodiment of the present disclosure.

FIG. 6 illustrates generating augmented data by calibrating a physical model associated with a physical trend using previous measurements, and using the calibrated physical model to predict additional measurements that conform to the physical trend, according to an embodiment of the present disclosure.

FIG. 7 illustrates generating the augmented data by calibrating, using previous measurements, a residue model configured to compensate for error in the predicted additional measurements, and generating the augmented data using the physical model and the residue model, according to an embodiment of the present disclosure.

FIG. 8 illustrates generating augmented data determined based on previous measurements and axes of symmetry in a pattern, according to an embodiment of the present disclosure.

FIG. 9 illustrates a focus/dose matrix that provides first data indicative of a focus trend and/or a dose trend, according to an embodiment of the present disclosure.

FIG. 10 illustrates thru-defocus data augmentation, according to an embodiment of the present disclosure.

FIG. 11 illustrates a physical trend defined by imaging characteristic (critical dimension in this example) measurements predicted by a physical model compared to predicted imaging characteristic measurements from a machine learning model that follow a similar trend, according to an embodiment of the present disclosure.

FIG. 12 (which is similar to FIG. 4) illustrates data used to augment previously determined imaging characteristic measurements made on actual substrates used to train a machine learning model (e.g., a neural network comprising multiple layers in this example), according to an embodiment of the present disclosure.

FIG. 13 is a block diagram of an example computer system, according to an embodiment of the present disclosure.

FIG. 14 is a schematic diagram of a lithographic projection apparatus, according to an embodiment of the present disclosure.

FIG. 15 is a schematic diagram of another lithographic projection apparatus, according to an embodiment of the present disclosure.

FIG. 16 is a detailed view of a lithographic projection apparatus, according to an embodiment of the present disclosure.

FIG. 17 is a detailed view of the source collector module of the lithographic projection apparatus, according to an embodiment of the present disclosure.

### DETAILED DESCRIPTION

As described above, machine learning models can be trained to predict imaging characteristics with respect to pattern variation on a wafer resulting from a patterning process. However, due to low pattern coverage provided by limited wafer data used for training, machine learning models tend to overfit, and predictions from the machine learning models deviate from physical trends that characterize the patterning process with respect to the pattern variation. For example, neural network based machine learning models have a strong ability to accurately fit predictions to training data, but are also prone to overfitting (e.g., for predictions that fall between or beyond training data points). In other words, a neural network based machine learning model can fit known data very well, but for new data, the accuracy of predictions from the model may be poor (e.g., due to overfitting).

Neural network based machine learning models typically require a large amount of data for model training to enhance prediction accuracy (e.g., to decrease the amount of possible new data the model might see, and reduce the likelihood of overfitting). However, due to patterning process and/or metrology resource constraints, and/or for other reasons, typically only a relatively few variations of a certain imaging characteristic (e.g., critical dimension, pitch, etc.) can be collected and used for model training. Increasing the pattern coverage by providing a large amount of patterning process and metrology resources is often prohibitively expensive.

As a practical example in semiconductor manufacturing, for one dimensional through pitch patterns, where the critical dimension (CD—described below) is kept constant while the pitch is varied, an etch bias is expected to have a smooth trend, reflecting a gradual change in material loading. However, in this example, only a relatively few data points are able to be measured and provided to a neural network based machine learning model for training. Thus, the neural network based machine learning model will tend to overfit. This means that the model will accurately fit etch bias predictions to training data, but is prone to overfitting for predictions that fall between training data points (e.g., a predicted etch bias trend line may undulate or otherwise vary between training data points in a way that does not reflect the smooth trend expected based on the process knowledge). This can lead to poor model prediction and inaccurate process adjustments and/or other applications based on the model, among other disadvantages.

According to embodiments described in the present disclosure, to enhance pattern coverage, training data is augmented by creating synthetic augmented data for new patterns based on a certain expected physical trend (e.g., the expected smooth etch bias trend in the example above), where the new patterns are not covered by previously measured wafer data. A physical trend of one or more imaging characteristics with respect to pattern variation on a substrate resulting from a patterning process is obtained or otherwise determined. The physical trend may be associated with pattern design variation and/or patterning process variation, for example. The physical trend is determined based on data for a first set of patterns and/or the patterning process. This data can be previously determined measurements of the pattern on the substrate, information indicative of a physical behavior of the pattern on the substrate resulting from the patterning process (e.g., process knowledge that an engineer already knows), and/or other data.

Synthetic augmented data is derived from the data for the first set of patterns and conforms to the physical trend. For example, augmented data may include data that is not covered in the previously determined measurements and/or the information indicative of the physical behavior of the pattern on the substrate, but still conforms to the physical trend. In some embodiments, this (first) data (e.g., the previously determined measurements and/or the information indicative of the physical behavior of the pattern on the substrate) may include actual measurements (e.g., values), but may also, in addition or instead, be information generated by a physical model, or even trend information simply known by a user. The augmented data is derived for a second set of patterns that are different from the first set. The augmented data can be provided as input to a machine learning model to train the machine learning model to predict the one or more imaging characteristics according to the physical trend (e.g., together with the first data). This can significantly increase machine learning model prediction accuracy (e.g., by reducing overfitting), without incurring additional metrology and/or other processing costs, among other advantages.

As another practical example, in each tuning iteration of the development cycle of a patterning process, new metrology data is recollected and typically must have sufficient pattern coverage to train a machine learning model and reduce model overfitting. This requires significant resources and creates a bottleneck for process development. Because an objective of model training target is to lower the absolute model error, data from previous iterations and similar tuning processes cannot be simply added to the current model training data, as pattern dimensions may be slightly different and could negatively impact the model performance if used as training data.

According to embodiments described in the present disclosure, data collected from similar tuning processes is used to augment any other available training data and improve the pattern coverage and regularize the machine learning model without incurring additional metrology and processing costs. For example, patterning processes from a same substrate layer may be similar between different process tuning iterations. However the metrology data from each iteration cannot be directly added to any other available model training data and treated the same as data collected from a current process (as described above). Instead, physical trends from the tuning process are determined, and available or newly generated data that conforms to those physical trends is used as training data. For example, tuning a patterning process may cause small variations to pattern critical dimensions, so the absolute metrology values from a given tuning iteration may not be directly used for training data. However the overall physical trends of the tuning processes may be the same as in a current patterning process. Thus, instead of using the absolute model error as a training objective, the machine learning model may be trained to follow the physical trends for the data from the similar processes. Augmented data used for training may comprise new data generated based on the physical trend and/or by a physical model, and/or a subset of previously determined measurements from an earlier patterning process tuning step that conforms to the physical trend. This augmented data is combinable with additional measurements from a current pattern or set of patterns on a current substrate produced by a current patterning process, for example.

Embodiments of the present disclosure are described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “projection optics,” as used herein, should be broadly interpreted as encompassing various types of optical systems, including refractive optics, reflective optics, apertures and catadioptric optics, for example. The term “projection optics” may also include components operating according to any of these design types for directing, shaping, or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the (e.g., semiconductor) patterning device, and/or optical components for shaping, adjusting and/or projecting the radiation after the radiation passes the patterning device. The projection optics generally exclude the source and the patterning device.

A (e.g., semiconductor) patterning device can comprise, or can form, one or more patterns. The pattern can be generated utilizing CAD (computer-aided design) programs, based on a pattern or design layout, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. The design rules may include and/or specify specific parameters, limits on and/or ranges for parameters, and/or other information. One or more of the design rule limitations and/or parameters may be referred to as a “critical dimension” (CD). A critical dimension of a device can be defined as the smallest width of a line or hole or the smallest space between two lines or two holes, or other features. Thus, the CD determines the overall size and density of the designed device. One of the goals in device fabrication is to faithfully reproduce the original design intent on the substrate (via the patterning device).

The term “mask” or “patterning device” as employed in this text may be broadly interpreted as referring to a generic semiconductor patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. An example of a programmable LCD array is given in U.S. Pat. No. 5,229,872, which is incorporated herein by reference.

As used herein, the term “patterning process” generally means a process that creates an etched substrate by the application of specified patterns of light as part of a lithography process. However, “patterning process” can also include (e.g., plasma) etching, as many of the features described herein can provide benefits to forming printed patterns using etch (e.g., plasma) processing.

As used herein, the term “pattern” means an idealized pattern that is to be etched on a substrate (e.g., wafer)—e.g., based on the design layout described above. A pattern may comprise, for example, various shape(s), arrangement(s) of features, contour(s), etc.

As used herein, a “printed pattern” means the physical pattern on a substrate that was etched based on a target pattern. The printed pattern can include, for example, troughs, channels, depressions, edges, or other two and three dimensional features resulting from a lithography process.

As used herein, the term “machine learning model”, “prediction model”, “process model”, “electronic model”, and/or “simulation model” (which may be used interchangeably) means a model that includes one or more models that simulate a patterning process. For example, a model can include an optical model (e.g., that models a lens system/projection system used to deliver light in a lithography process and may include modelling the final optical image of light that goes onto a photoresist), a resist model (e.g., that models physical effects of the resist, such as chemical effects due to the light), an OPC model (e.g., that can be used to make target patterns and may include sub-resolution resist features (SRAFs), etc.), an etch (or etch bias) model (e.g., that simulates the physical effects of an etching process on a printed wafer pattern), a source mask optimization (SMO) model, and/or other models.

As used herein, the term “calibrating” means to modify (e.g., improve or tune) and/or validate something, such as a model.

A patterning system may be a system comprising any or all of the components described above, plus other components configured to performing any or all of the operations associated with these components. A patterning system may include a lithographic projection apparatus, a scanner, systems configured to apply and/or remove resist, etching systems, and/or other systems, for example.

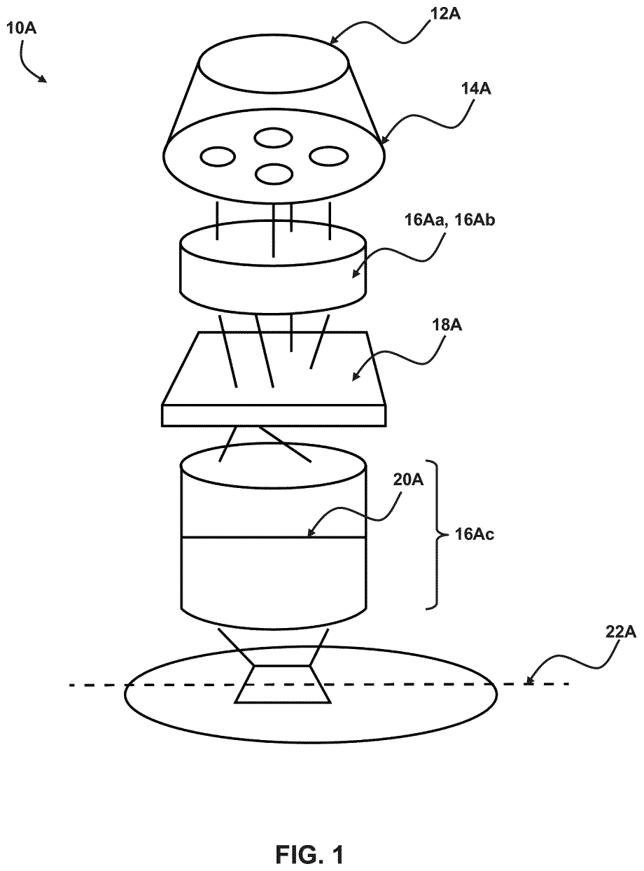

As an introduction, FIG. 1 illustrates a diagram of various subsystems of an example lithographic projection apparatus 10A. Major components are a radiation source 12A, which may be a deep-ultraviolet excimer laser source or other type of source including an extreme ultra violet (EUV) source (however, the lithographic projection apparatus itself need not have the radiation source), illumination optics which, for example, define the partial coherence (denoted as sigma) and which may include optics components 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related to properties of the resist layer (e.g., effects of chemical processes which occur during exposure, post-exposure bake (PEB) and development). Optical properties of the lithographic projection apparatus (e.g., properties of the illumination, the patterning device, and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

It may be desirable to use one or more tools to produce results that, for example, can be used to design, control, monitor, etc. the patterning process. One or more tools used in computationally controlling, designing, etc. one or more aspects of the patterning process, such as the pattern design for a patterning device (including, for example, adding sub-resolution assist features or optical proximity corrections), the illumination for the patterning device, etc., may be provided. Accordingly, in a system for computationally controlling, designing, etc. a manufacturing process involving patterning, the manufacturing system components and/or processes can be described by various functional modules and/or models. In some embodiments, one or more electronic (e.g., mathematical, parameterized, machine learning, physical, etc.) models may be provided that describe one or more steps and/or apparatuses of the patterning process. In some embodiments, a simulation of the patterning process can be performed using one or more electronic models to simulate how the patterning process forms a patterned substrate using a pattern provided by a patterning device.

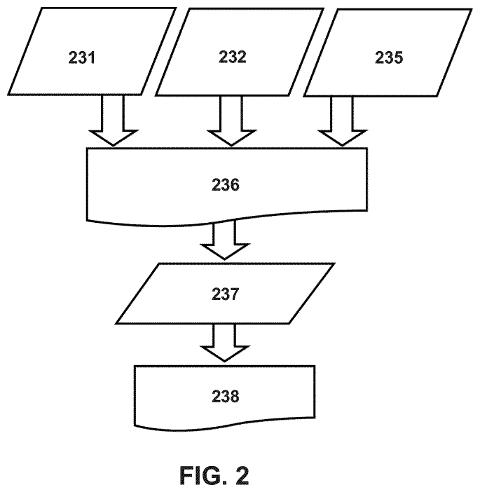

An exemplary flow chart for simulating lithography in a lithographic projection apparatus is illustrated in FIG. 2. An illumination model 231 represents optical characteristics (including radiation intensity distribution and/or phase distribution) of the illumination. A projection optics model 232 represents optical characteristics (including changes to the radiation intensity distribution and/or the phase distribution caused by the projection optics) of the projection optics. A design layout model 235 represents optical characteristics (including changes to the radiation intensity distribution and/or the phase distribution caused by a given design layout) of a design layout, which is the representation of an arrangement of features on or formed by a patterning device. An aerial image 236 can be simulated using the illumination model 231, the projection optics model 232, and the design layout model 235. A resist image 238 can be simulated from the aerial image 236 using a resist model 237. Simulation of lithography can, for example, predict contours and/or CDs in the resist image.

More specifically, illumination model 231 can represent the optical characteristics of the illumination that include, but are not limited to, NA-sigma (σ) settings as well as any particular illumination shape (e.g. off-axis illumination such as annular, quadrupole, dipole, etc.). The projection optics model 232 can represent the optical characteristics of the of the projection optics, including, for example, aberration, distortion, a refractive index, a physical size or dimension, etc. The design layout model 235 can also represent one or more physical properties of a physical patterning device, as described, for example, in U.S. Pat. No. 7,587,704, which is incorporated by reference in its entirety. Optical properties associated with the lithographic projection apparatus (e.g., properties of the illumination, the patterning device, and the projection optics) dictate the aerial image. Since the patterning device used in the lithographic projection apparatus can be changed, it is desirable to separate the optical properties of the patterning device from the optical properties of the rest of the lithographic projection apparatus including at least the illumination and the projection optics (hence design layout model 235).

The resist model 237 can be used to calculate the resist image from the aerial image, an example of which can be found in U.S. Pat. No. 8,200,468, which is hereby incorporated by reference in its entirety. The resist model is typically related to properties of the resist layer (e.g., effects of chemical processes which occur during exposure, post-exposure bake and/or development).

One of the objectives of the full simulation is to accurately predict, for example, edge placements, aerial image intensity slopes and/or CDs, which can then be compared against an intended design. The intended design is generally defined as a pre-OPC design (or pattern) layout which can be provided in a standardized digital file format such as .GDS, .GDSII, .OASIS, or other file formats.

From the design (pattern) layout, one or more portions may be identified, which are referred to as “clips.” In an embodiment, a set of clips is extracted, which represents the complicated patterns in the design (pattern) layout (often hundreds or thousands of clips, although any number of clips may be used). As will be appreciated by those skilled in the art, these clips represent small portions (e.g., circuits, cells, etc.) of the design and may represent small portions for which particular attention and/or verification is needed. In other words, clips may be the portions of the design (pattern) layout or may be similar or have a similar behavior of portions of the design (pattern) layout where critical features are identified either by experience (including clips provided by a customer), by trial and error, or by running a full-chip simulation. Clips may contain one or more test patterns or gauge patterns. An initial larger set of clips may be provided a priori by a customer based on known critical feature areas in a design (pattern) layout which require particular image optimization. Alternatively, in another embodiment, the initial larger set of clips may be extracted from the entire design (pattern) layout by using an automated (such as, machine vision) or manual algorithm that identifies the critical feature areas.

Based on the clips (and/or other information), simulation and modeling can be used to configure one or more features of the patterning device pattern (e.g., performing optical proximity correction), one or more features of the illumination (e.g., changing one or more characteristics of a spatial/angular intensity distribution of the illumination, such as change a shape), and/or one or more features of the projection optics (e.g., numerical aperture, etc.). Such configuration can be generally referred to as, respectively, mask optimization, source optimization, and projection optimization. Such optimization can be performed on their own, or combined in different combinations. One such example is source-mask optimization (SMO), which involves the configuring of one or more features of the patterning device pattern together with one or more features of the illumination. The optimization techniques may focus on one or more of the clips.

Similar modelling techniques may be applied for optimizing an etching process, for example, and/or other processes. In some embodiments, illumination model 231, projection optics model 232, design layout model 235, resist model 237, and/or other models may be used in conjunction with an etch model, for example. For example, output from an after development inspection (ADI) model (e.g., included as some and/or all of design layout model 235, resist model 237, and/or other models) may be used to determine an ADI contour, which may be provided to an effective etch bias (EEB) model to generate a predicted after etch inspection (AEI) contour.

In some embodiments, an optimization process of a system may be represented as a cost function. The optimization process may comprise finding a set of parameters (design variables, process variables, etc.) of the system that minimizes the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics. The cost function can also be the maximum of these deviations (i.e., worst deviation). The term “evaluation points” should be interpreted broadly to include any characteristics of the system or fabrication method. The design and/or process variables of the system can be confined to finite ranges and/or be interdependent due to practicalities of implementations of the system and/or method. In the case of a lithographic projection apparatus, the constraints are often associated with physical properties and characteristics of the hardware such as tunable ranges, and/or patterning device manufacturability design rules. The evaluation points can include physical points on a resist image on a substrate, as well as non-physical characteristics such as one or more etching parameters, dose and focus, etc., for example.

In an etching system, as an example, a cost function (CF) may be expressed as

$$\\ CF ( {z}_{1} , {z}_{2} , … , {z}_{N} ) = {\sum }_{p = 1}^{P} {w}_{p} {f}_{p}^{{}_{} 2} ( {z}_{1} , {z}_{2} , … , {z}_{N} )$$

where (z₁, z₂, . . . , z_{N}) are N design variables or values thereof, and ƒₚ(z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). In some embodiments, wₚ is a weight constant associated with ƒₚ(z₁, z₂, . . . , z_{N}). For example, the characteristic may be a position of an edge of a pattern, measured at a given point on the edge.

Different ƒₚ(z₁, z₂, . . . , z_{N}) may have different weight wₚ. For example, if a particular edge has a narrow range of permitted positions, the weight wₚ for the ƒₚ(z₁, z₂, . . . , z_{N}) representing the difference between the actual position and the intended position of the edge may be given a higher value. ƒₚ(z₁, z₂, . . . , z_{N}) can also be a function of an interlayer characteristic, which is in turn a function of the design variables (z₁, z₂, . . . , z_{N}). Of course, CF(z₁, z₂, . . . , z_{N}) is not limited to the form in the equation above and CF(z₁, z₂, . . . , z_{N}) can be in any other suitable form.

The cost function may represent any one or more suitable characteristics of the etching system, etching process, lithographic apparatus, lithography process, or the substrate, for instance, focus, CD, image shift, image distortion, image rotation, stochastic variation, throughput, local CD variation, process window, an interlayer characteristic, or a combination thereof. In some embodiments, the cost function may include a function that represents one or more characteristics of a resist image. For example, ƒₚ(z₁, z₂, . . . , z_{N}) can be simply a distance between a point in the resist image to an intended position of that point (i.e., edge placement error EPEₚ(z₁, z₂, . . . , z_{N}) after etching, for example, and/or some other process. The parameters (e.g., design variables) can include any adjustable parameter such as an adjustable parameter of the etching system, the source, the patterning device, the projection optics, dose, focus, etc.

The parameters (e.g., design variables) may have constraints, which can be expressed as (z₁, z₂, . . . , z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. Constraints should not be interpreted as a necessity.

In some embodiments, illumination model 231, projection optics model 232, design layout model 235, resist model 237, an etch model, and/or other models associated with and/or included in an integrated circuit manufacturing process may be an empirical and/or other simulation model. The empirical model may predict outputs based on correlations between various inputs (e.g., one or more characteristics of a pattern, one or more characteristics of the patterning device, one or more characteristics of the illumination used in the lithographic process such as the wavelength, etc.).

As an example, the empirical model may be a machine learning model and/or any other parameterized model. In some embodiments, the machine learning model (for example) may be and/or include mathematical equations, algorithms, plots, charts, networks (e.g., neural networks), and/or other tools and machine learning model components. For example, the machine learning model may be and/or include one or more neural networks having an input layer, an output layer, and one or more intermediate or hidden layers. In some embodiments, the one or more neural networks may be and/or include deep neural networks (e.g., neural networks that have one or more intermediate or hidden layers between the input and output layers).

As an example, the one or more neural networks may be based on a large collection of neural units (or artificial neurons). The one or more neural networks may loosely mimic the manner in which a biological brain works (e.g., via large clusters of biological neurons connected by axons). Each neural unit of a neural network may be connected with many other neural units of the neural network. Such connections can be enforcing or inhibitory in their effect on the activation state of connected neural units. In some embodiments, each individual neural unit may have a summation function that combines the values of all its inputs together. In some embodiments, each connection (or the neural unit itself) may have a threshold function such that a signal must surpass the threshold before it is allowed to propagate to other neural units. These neural network systems may be self-learning and trained, rather than explicitly programmed, and can perform significantly better in certain areas of problem solving, as compared to traditional computer programs. In some embodiments, the one or more neural networks may include multiple layers (e.g., where a signal path traverses from front layers to back layers). In some embodiments, back propagation techniques may be utilized by the neural networks, where forward stimulation is used to reset weights on the “front” neural units. In some embodiments, stimulation and inhibition for the one or more neural networks may be freer flowing, with connections interacting in a more chaotic and complex fashion. In some embodiments, the intermediate layers of the one or more neural networks include one or more convolutional layers, one or more recurrent layers, and/or other layers.

The one or more neural networks may be trained (i.e., whose parameters are determined) using a set of training data and/or other information. The training data and/or other information may include a set of training samples. Each sample may be a pair comprising an input object (typically a vector, which may be called a feature vector) and a desired output value (also called the supervisory signal). A training algorithm analyzes the training information and adjusts the behavior of the neural network by adjusting the parameters (e.g., weights of one or more layers) of the neural network based on the training data and/or other information. For example, given a set of N training samples of the form {(x₁, y₁), (x₂, y₂), . . . , (x_{N}, y_{N})} such that xᵢ is the feature vector of the i-th example and yᵢ is its supervisory signal, a training algorithm seeks a neural network g: X→Y, where X is the input space and Y is the output space. A feature vector is an n-dimensional vector of numerical features that represent some object (e.g., a simulated aerial image, a wafer design, a clip, etc.). The vector space associated with these vectors is often called the feature space. After training, the neural network may be used for making predictions using new samples.

As another example, an empirical (simulation) model may comprise one or more algorithms. The one or more algorithms may be and/or include mathematical equations, plots, charts, and/or other tools and model components. In some embodiments, an empirical (simulation) model is a physical model comprising one or more algorithms with terms that collectively simulate the physical behavior of a pattern on a substrate, a patterning process, etc.

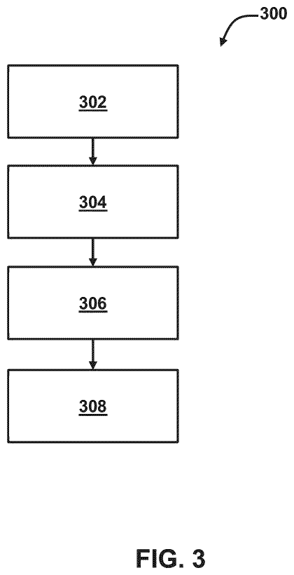

FIG. 3 illustrates an exemplary method 300 for generating augmented data, according to an embodiment of the present disclosure. The augmented data is used to augment any other available data used to train a machine learning model. The augmented data is determined based on a physical trend associated with a set of patterns on a substrate and/or process variation resulting from a patterning process. The augmented data is configured to enhance a prediction accuracy of a machine learning model relative to prior models.

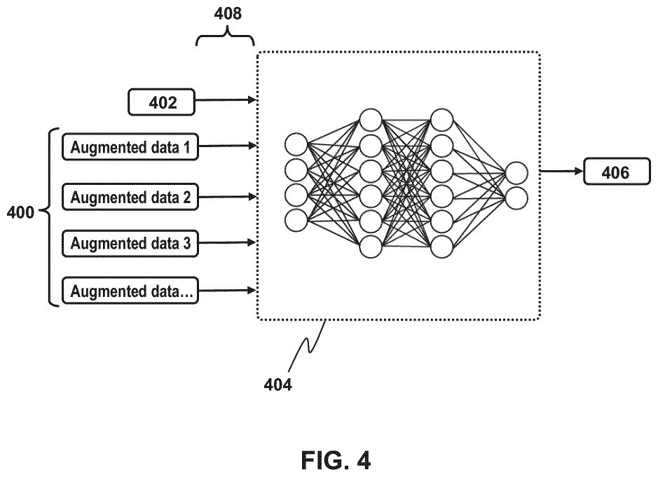

For example, FIG. 4 illustrates data 400 used to augment (see Augmented data 1 to Augmented data . . . ) data 402 (e.g., which may be previously determined) used to train a neural network 404 of a machine learning model (e.g., a neural network comprising multiple layers in this example) 406. Data 400 is determined based on one or more physical trends associated with a set of patterns on a substrate and/or process variation resulting from a patterning process. Data 400 is provided together with data 402 (in this example) as input 408 to train neural network 404 of machine learning model 406. Using data 400 in training model 406 can advantageously improve the accuracy of model predictions.

Returning to FIG. 3, in some embodiments, method 300 comprises obtaining 302 or otherwise determining a physical trend (e.g., a physical trend of a certain characteristic with respect to pattern variation), generating 304 the augmented data, providing 306 the augmented data to the machine learning model (e.g., by itself, together with measured data, and/or together with other (e.g., unrelated) data) to train the machine learning model, and providing 308 output from the machine leaning model for various downstream applications.

In some embodiments, a non-transitory computer readable medium stores instructions which, when executed by a computer, cause the computer to execute one or more of operations 302-308, and/or other operations. The operations of method 300 are intended to be illustrative. In some embodiments, method 300 may be accomplished with one or more additional operations not described, and/or without one or more of the operations discussed. For example, operation 308 and/or other operations may be optional. Additionally, the order in which the operations of method 300 are illustrated in FIG. 3 and described herein is not intended to be limiting.

At an operation 302, a physical trend of one or more imaging characteristics with respect to pattern variation on a substrate is obtained or otherwise determined, where the imaging characteristics are associated with a patterning process. The patterning process may be a lithography process, an etching process, and/or other processes. In some embodiments, the one or more imaging characteristics comprise a critical dimension (CD), an edge placement location, a curvature, a pitch, a symmetry, a rotation, an aspect ratio, an offset, and/or other imaging characteristics.

The physical trend may be a physics based indication of tendency that an imaging characteristic changes. A physical trend describes how the imaging characteristics will respond/change in the “real world”, or according to physical principles, when the pattern design or process conditions change. The physical trend may be associated with pattern design variation (e.g., variation in imaging characteristics such as CD, pitch, etc.) and/or patterning process variation (e.g., changes in the imaging characteristics caused by variation in dose, focus, etc.; etching process variation such as source power, bias power, etching time, gas chemistry, gas flow, etc.), for example. The physical trend is obtained based on (e.g., first) data for a (e.g., first) set of patterns, and/or patterning process. In some embodiments, this (first) data comprises previously determined measurements of the imaging characteristics for the pattern on the substrate, information indicative of a physical behavior of the pattern on the substrate resulting from or during the patterning process, and/or other data.

The present disclosure is not limited to any mechanism or source of information that can be used to determine a physical trend. In some embodiments, this (first) data may include actual measurements (e.g., values), but may also, in addition or instead, be information output by a physical model, or trend information defined by a user. First data for a first set of patterns and/or a patterning process could be measurements, information from a physical model, and/or trend information defined by a user. For example, process knowledge (e.g., first data) may dictate that an etch bias versus pitch should be a smooth trend, reflecting a gradual change in material loading during an etching process.

For example, in some embodiments, the first data may comprise previously determined measurements of a first pattern or set of patterns on a first substrate produced by a first patterning process. A physical trend may be obtained and/or otherwise determined by (1) extracting and/or categorizing measurements of the first pattern or set of patterns on the first substrate associated with the physical trend, and/or (2) fitting a physical model to the measurements of the first pattern or set of patterns. In this example, the first patterning process may comprise one or more first semiconductor manufacturing pattern tuning processes that have similar and comparable process conditions with a second patterning process. The second patterning process may comprises the actual current manufacturing patterning process, another target patterning process, some other final patterning process, a patterning process which is simulated and/or for which a model is constructed, and/or another patterning process.

At an operation 304, augmented data (which is used for training as described herein) is generated. The augmented data is generated based on the physical trend (determined at operation 302), and/or other information. The augmented data comprises (e.g., second) data that conforms to the physical trend and is derived based on the (e.g., first) data for the set of patterns and/or the patterning process described above. In other words, the augmented data is not random or uncontrolled. In contrast, the (second) data that conforms to the physical trend comprises data that conforms to, or is confined within, certain expected data value thresholds that represent the physical limits of what would be expected from a known pattern and/or patterning process for a given process input. The physical trend determines the relative value/position of the imaging characteristics, for example. In some embodiments, the physical trend may dictate the value of augmented data according to measured actual data, for example. The degree of conformity can be described by, for example, the error (but in reality the error is in interpolating/generating the trend from existing data and generating the augmented data from the trend should carry no error). In some embodiments, the trend controls the relative values or relationships among the augmented data. For example the slope or shape of trend curves (e.g., as described herein). The augmented data is derived for a different (e.g., second) set of patterns. The augmented data is new relative to previously determined measurements and/or the information indicative of the physical behavior of the pattern on the substrate (e.g., the first data), but still conforms to the physical trend.

Returning to the example above, if process definition (e.g., by a user) and/or prior measurements (e.g., first data) dictated that an etch bias versus pitch should be a smooth trend, reflecting a gradual change in material loading, generated augmented data (e.g., second data) would be confined within certain etch bias value thresholds that represent the gradual change that would be expected from a known etching process. It should be noted that training data may include synthesized augmented data (e.g., second data) alone, and/or the newly generated data together with the prior measurements (e.g., the first data).

The synthesized augmented data can be used to augment any already existing data. In some embodiments, training data includes the first data, the second data (e.g., the augmented data), and/or other data. In some embodiments, training data comprises a new and/or additional set of measurements of the imaging characteristics configured to augment any measurements of the imaging characteristics included in the first data, for example. In some embodiments, the weighting of the additional (e.g., second) data can be adjusted relative to the already existing data, and then provided for training (as described below).

In general, operation 304 comprises generating augmented data (to be used for training) based on a physical trend to improve pattern coverage and regularize a machine learning model (see operation 306 described below), without incurring additional metrology and processing costs associated with generating training data. Two main types of augmented (training) data that are generated based on a physical trend are contemplated (though other types may be possible)—(1) metrology data based augmentation; and (2) non-metrology based, trend-only based data augmentation.

With regard to metrology data based augmentation, in some embodiments, data points for the physical trend may have been previously measured and be available as training data. The metrology data based augmentation described herein can significantly enhance the data density for data describing the physical trend to ensure that (once trained using the additional training data generated at operation 304) predictions from the machine learning model conform to the physical trend (see operation 306 described below). For example, in some embodiments, the augmented training data is generated based on previous measurements of one or more imaging characteristics. These may be included in the first data, for example, such that the first data comprises previously determined data for the (e.g., first) set of patterns and/or the patterning process that at least partially defines the physical trend.

In some embodiments, generating the augmented data comprises mathematically interpolating between measurements of a given imaging characteristic with respect to pattern variation to determine additional measurement data points for the given imaging characteristic. This may include identifying a physical trend (operation 302) of the imaging characteristics with respect to pattern variation, such as a physical trend describing through pitch behavior or through CD behavior, and obtaining any corresponding previous measurements. In some embodiments, the physical trend may be described by an equation in two dimensional space (e.g., by an equation that relates how a dependent variable Y varies with an independent variable X), for example. The physical trend may be determined based on the previous measurements, for example, and/or other information. This may include determining a mathematical or other relationship between previous measurements, or other operations (e.g., a mathematical relationship between an independent variable and a dependent variable).

Mathematical interpolation between previous measurements can be used to determine expected imaging characteristic measurement data for intermediate points between previous measurements (e.g., points that correspond to an independent variable X such as pattern CD, pitch, etc.). The interpolation may comprise linear interpolation, spline fitting, and/or other techniques to ensure that expected imaging characteristic measurement data for intermediate points conforms to the physical trend. The interpolation may be used to generate additional intermediate measurement data points. The number and density of generated data points can be flexible, from just a few points to even several thousand data points, for example.

Augmentation data may be generated at those intermediate points and gauges may be set and/or otherwise determined based on expected measurements (e.g., values), for example. The additional (e.g., gauge) data may be added to the previous measurements and fed to the machine learning model for training (as described below).

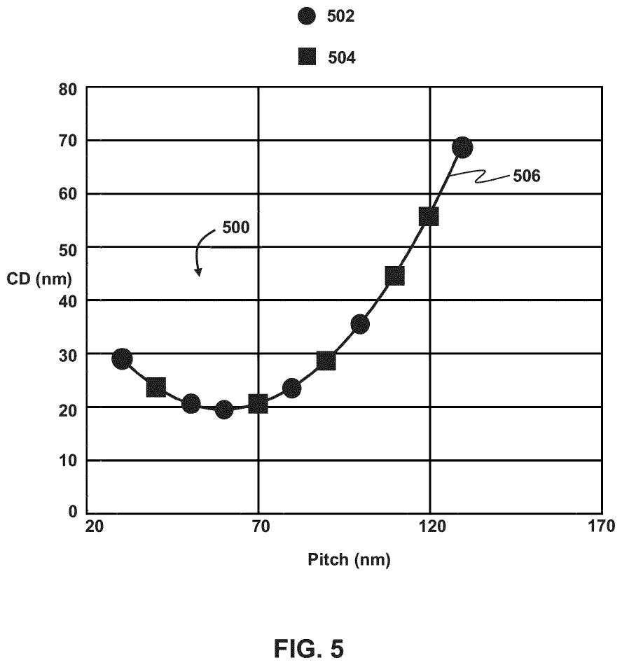

By way of a non-limiting example, FIG. 5 illustrates generating augmented data 500 by mathematically interpolating between measurements 502 of a given imaging characteristic (e.g., CD in this example) to determine additional (interpolated) measurement data points 504 (e.g., augmented data) for the given imaging characteristic. In this example, the series of measurements 502 followed a certain physical trend shown by trend line 506. Via interpolation, a measurement sampling density is increased along trend line 506.

Returning to FIG. 3, in some embodiments, at operation 304, generating the augmented data comprises calibrating a physical model associated with the physical trend using the measurements, and using the calibrated physical model to predict additional measurements that conform to the physical trend. This may again include determining a physical trend (operation 302), such as a physical trend describing through pitch behavior or through CD behavior (e.g., based on previous data), and obtaining any corresponding previous measurements. In some embodiments, the calibrated physical model may be configured to predict the physical trend (e.g., based on the previous measurements and/or other information). The physical model may be a multi-dimensional algorithm having terms that collectively simulate the physical trend and/or the patterning process, for example.

The physical model is calibrated using some or all of the obtained previous measurements. In some embodiments, a more limited set of measurements used for calibration may help the physical model to achieve high accuracy and faithfully capture the physical trend. The physical model may be used to generate additional intermediate measurement data points for the physical trend. The number and density of generated data points can be flexible depending on the trend, from just a few points to even several thousand data points, for example.

Augmentation data may be generated at intermediate points and gauges may be set and/or otherwise determined based on predicted measurement data points, for example. The calibrated physical model is used to generate the target values for the augmented data. In some embodiments, one or more of the obtained previous measurements may be replaced with corresponding predictions from the physical model. The additional data may be added to the previous measurements, and/or used to replace the previous measurements, and provided as input to the machine learning model for training (as described below).

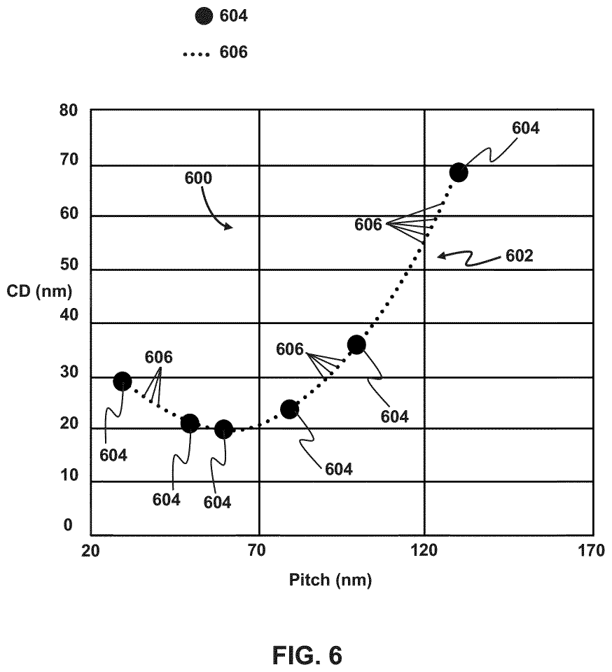

By way of a non-limiting example, FIG. 6 illustrates a physical trend line 602. FIG. 6 illustrates generating augmented data 600 by calibrating a physical mode using previous (CD) measurements 604 (in this example), and then using the calibrated physical model to predict additional measurements 606 that conform to the physical trend (e.g., line along trend line 602). In this example, the series of measurements 604 followed a certain physical trend evident in the data shown by trend line 602. The density of additional measurements 606 is significantly increased relative to the density of previous measurements 604. Predicted additional measurements 606 can be used (with or without measurements 604) for machine learning model training (as described herein).

Returning to FIG. 3, in some embodiments, at operation 304, generating the augmented data further comprises calibrating, using previous measurements, a residue model configured to compensate for error in the predicted additional measurements, and generating the augmented data using the physical model and the residue model. The residue model may compensate for inaccuracy in the physical model for example. In some embodiments, the residue model comprises a mathematical model calibrated by fitting (e.g., linear or spline fitting, etc.) errors in predictions from the physical model to the previous measurements.

This may again include identifying (e.g., predicting using the calibrated physical model as described above) a physical trend (operation 302), such as a physical trend (e.g., an equation) describing through pitch behavior or through CD behavior, and obtaining any corresponding previous measurements. The physical model may again be calibrated using some or all of the obtained previous measurements. The residue model is calibrated to capture the relationship between a predictor variable and the model error of the physical model (e.g., for each pattern type). The physical model may be used to generate additional intermediate measurement data points for the physical trend. The number and density of generated data points can be flexible depending on the trend, from just a few points to even several thousand data points, for example.

Augmentation data may be generated at intermediate points and gauges may be set and/or otherwise determined based on predicted measurement data points, for example. A model check may be performed using the generated data and the physical model. In some embodiments, one or more of the obtained previous measurements may be replaced with corresponding error compensated predictions of additional measurements from the physical model. An error compensated prediction of an additional measurement comprises a predicted measurement data point from the physical model adjusted by an estimated model error from the residue model. The error compensated additional measurement data may be added to the previous measurements, and/or used to replace the previous measurements, and fed to the machine learning model for training (as described below).

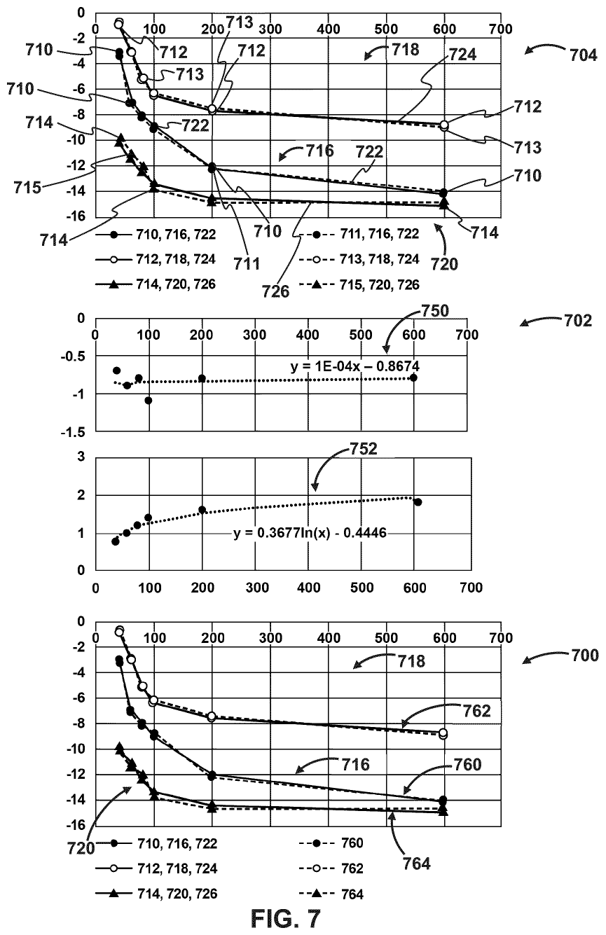

By way of a non-limiting example, FIG. 7 illustrates generating the augmented data 700 by calibrating, using previous measurements, a residue model configured to compensate for error 702 in the predicted additional measurements 704, and generating the augmented data using the physical model and the residue model. FIG. 7 illustrates etch bias measurements (e.g., values), in this example, 710, 712, 714 for different pattern types 716, 718, 720 that follow different physical trends 722, 724, 726. (Prior examples in this disclosure have focused on a single pattern type, but could have easily included additional pattern types as shown here in FIG. 7.) FIG. 7 also illustrates predicted bias measurements 711, 713, 715 for the different pattern types 716, 718, 720 that generally follow the physical trends 722, 724, 726. Note that there are slight differences (e.g., there is error) between etch bias measurements 710 and 712 and corresponding predicted etch bias measurements 711 and 713 for pattern types 716 and 718. These slight differences (error) is described by equations 750 and 752 for pattern types 716 and 718 respectively (there was very little error in the predictions for etch bias measurements 714). The residue model is configured to compensate for the error in the predicted etch bias measurements 710 and 712 for pattern types 716 and 718 using equations 750 and 752 (in this example), respectively. As shown in FIG. 7, error compensated predictions 760, 762, and 764 align closely with etch bias measurements 710, 712, 714 for different pattern types 716, 718, 720 that follow the different physical trends 722, 724, 726. Error compensated predictions 760, 762, and 764 can be used (with or without previous etch bias measurements 710, 712, and 714) for machine learning model training (as described herein).

Returning to FIG. 3, in some embodiments, at operation 304, generating the augmented data is based on the previous measurements and symmetry in the pattern. For example, a pattern may have one or more portions that are symmetric with one or more other portions of the pattern. These symmetries may be known by operators, determined based on the pattern itself, and/or determined in other ways. If pattern symmetries are known, and metrology data about one symmetric portion of the pattern is obtained, metrology data about the other symmetric portions of the pattern may be determined based on the symmetries. The symmetries include translational symmetry, rotational symmetry, reflective symmetry, glide symmetry, and/or other symmetries.

In some embodiments, generating the augmented data based on the previous measurements and symmetry in the pattern resulting from the patterning process comprises identifying one or more portions of symmetry in the pattern, and obtaining corresponding previous measurements for that portion of the pattern. Additional measurements for the pattern may be determined by mathematically duplicating previous measurements onto symmetrical counterpart portions of the pattern (e.g., using equations for translational, rotational, reflective, glide, and/or other symmetries). The additional symmetry based measurement data may be added to the previous measurements, and/or used to replace the previous measurements, and fed to the machine learning model for training (as described below).

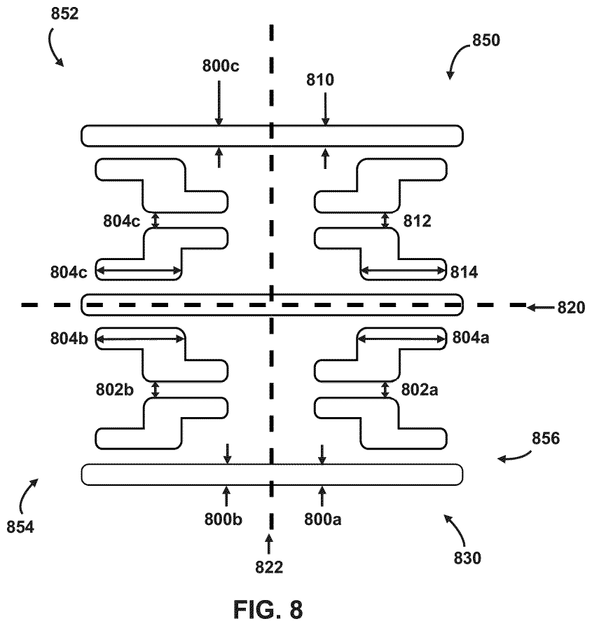

By way of a non-limiting example, FIG. 8 illustrates generating augmented data 800a, b, c; 802 a, b, c; and 804a, b, c, determined based on previous measurements 810, 812, 814 and axes of symmetry 820, 822 in a pattern 830. For example, pattern 830 may have a portion 850 that is symmetric with one or more other portions 852, 854, 856 of pattern 830. If pattern 830 symmetries are known, and metrology data about one symmetric portion 850 of the pattern is obtained, metrology data about the other symmetric portions 852, 854, 856 of pattern 830 may be determined based on the symmetries. In this example, additional symmetry based measurement data 800a, b, c; 802 a, b, c; and 804a, b, c, may be added to previous measurements 810, 812, 814, and/or used to replace previous measurements 810, 812, 814, and fed to the machine learning model for training (as described below).

With regard to non-metrology, trend-only based data augmentation, there may be no available previous measurements (e.g., metrology data), but a certain physical trend may be known. This physical trend may be known based on a physical model, physics knowledge, and/or other information. In these embodiments, the machine learning model is trained to follow the physical trend, rather than any actual absolute previous measurements.

For example, in some embodiments, generating the augmented data at operation 304 comprises determining the physical trend based on outputs from a trained physical model. The trend may be described by relative relationships between measurements (e.g., values) of imaging characteristics predicted by the physical model, rather than absolute values of the imaging characteristics themselves. In some embodiments, the physical trend comprises a symmetry trend, an orientation trend, a focus trend, a dose trend, a through pitch trend, a linearity trend, a through critical dimension trend, and/or other trends.

In some embodiments, for a focus/dose trend, a physical model may be used to simulate CD (as one example) variations caused by focus/dose perturbation. Focus/dose trend data may be collected and then provided as input to the machine learning model for training (e.g., using the “STD” loss function described below). In some embodiments, for a through pitch trend, mask CD (as one example) may be kept constant while pitch is changed. A physical model may be used to determine model CD versus pitch trends. This trend data may be provided as input to the machine learning model for training (e.g., again using the “STD” loss function described below). In some embodiments, for a linearity trend, pitch (as one example) may be kept constant with mask CD is changed. A physical model may be used to determine CD versus CD trends. This trend data may be provided as input to the machine learning model for training (e.g., again using the “STD” loss function described below). Other similar operations may be performed for other trends such as a through critical dimension trend, and/or other trends.

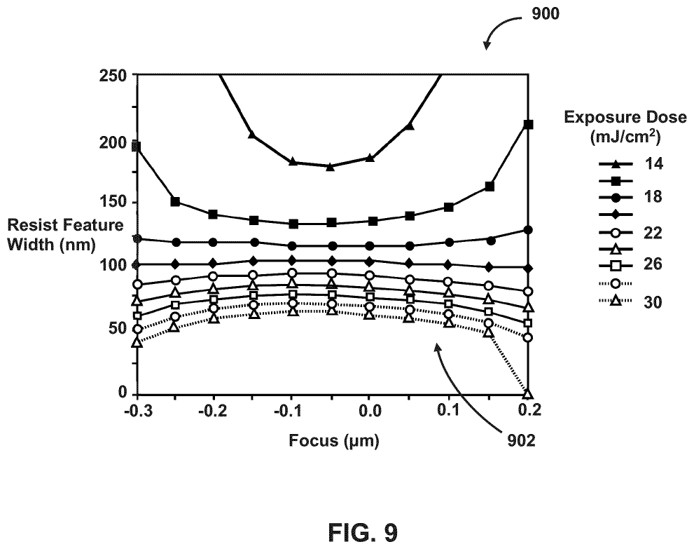

By way of a non-limiting example, FIG. 9 illustrates a focus/dose matrix 900 that provides first data 902 indicative of a focus trend and/or a dose trend. This data may be readily available from a simulation by a physical model, for example. In the absence of a substrate CD (or other imaging characteristics), for example, focus/dose trends can be used to guide machine learning model training (e.g., as described below at operation 306).

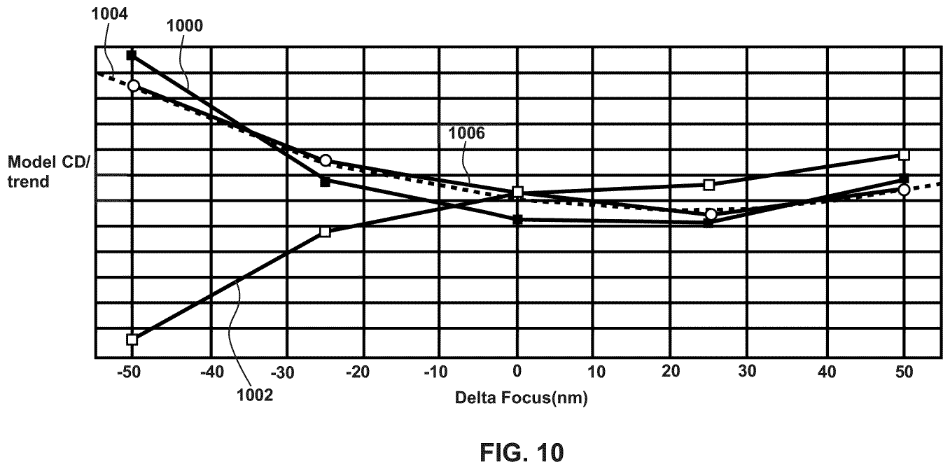

As another non-limiting example, FIG. 10 illustrates thru-defocus data augmentation. FIG. 10 illustrates generated augmented data values 1006 from a physical trend and a nominal wafer CD from a machine learning model trained using augmented data generated based on a focus exposure matrix (FEM) physical trend. FIG. 10 illustrates values 1006 relative to a dotted line 1004 that represents a known physical trend, values 1002 from a machine learning model trained without any data augmentation, and predicted CD values 1000 from a machine learning model trained with data augmentation based on previous measurements (e.g., as described above). As shown in FIG. 10, augmenting machine learning model training with additional training data corrects the trend originally associated with values 1002 (which do not follow the known physical trend illustrated by line 1004). In this example, actual CD CE data was originally (e.g., before augmentation) only available at a nominal condition (zero defocus). A physical model was used to add additional trend information, and/or data predicted according to the physical trend, to enhance predictions from the machine learning model (e.g., to better match line 1004).

Returning to FIG. 3, in some embodiments, the augmented data comprises new data generated based on the physical trend and/or by a physical model, a subset of previously determined measurements (e.g., from the first data described above) that conforms to a physical trend, and/or other data. The augmented data is combinable with second measurements from a second pattern or set of patterns on a second substrate produced by a second patterning process. As described above, the second patterning process may be the actual manufacturing patterning process, another target patterning process, some other final patterning process, a patterning process which is simulated and/or for which a model is constructed, and/or another patterning process. The subset of the previously determined measurements from the first data that conforms to the physical trend may comprise data associated with a previous mask when a first patterning process and the second patterning process are similar, for example. In some embodiments, the subset of the previously determined measurements from the first data that conforms to the physical trend comprises data associated with different locations on a current mask when the second patterning process is adjusted relative to the first patterning process, for example.

In some embodiments, the second data comprises less second measurements from a second pattern on a second substrate produced by a second patterning process compared to a quantity of the first measurements. The less second measurements are combinable with the new data generated based on the physical trend and/or by the physical model, and/or the subset of the previously determined measurements from the first data that conforms to the physical trend. In some embodiments, a total amount of augmented data has a same or increased data density relative to previously determined measurements (e.g., measurements of a first pattern on a first substrate produced by a first patterning process).

At an operation 306, the augmented data is provided to a machine learning model to train the machine learning model. The augmented data is configured to be provided as input to the machine learning model to train the machine learning model to predict the one or more imaging characteristics according to the physical trend. In some embodiments, this comprises providing the augmented data as input to the machine learning model to train the machine learning model to conform predictions of the one or more imaging characteristics according to the physical trend. Data that conforms to the physical trend comprises data that conforms to, or is confined within, certain expected data value thresholds that represent the physical limits of what would be expected from a known physical trend for a pattern and/or patterning process for a given process input.

In some embodiments, the machine learning model is trained to predict the one or more imaging characteristics according to the physical trend based on a loss function. A loss function comprises an algorithm configured to evaluate how well the machine learning model models the training data set. Training the machine learning model to predict the one or more imaging characteristics according to the physical trend based on a loss function may reinforce and/or otherwise cause the machine learning model to ensure predictions conform to the physical trend.

With regard to metrology data based augmentation by any of the operations described above related to FIGS. 5-8, the augmented data is as trustworthy as the previously determined measurements. The present systems and methods are configured to reduce the error between the values predicted by the machine learning model and that of the interpolated value/value from the physical model. For example, a root mean square (RMS) loss function can be applied to drive machine learning model training convergence. For example, the loss function may comprise:

$$\\ RMS = \sqrt{\frac{\sum {( {CD}_{i} - {CD}_{measured} )}^{2}}{N}}$$

where CDᵢ comprises a predicted CD measurement, CD_{measured} is a corresponding previously determined (e.g., actual) CD measurement, and N is a measurement number. Note that CD is interchangeable with other possible imaging characteristics in this example. CD is used here as an example imaging characteristic. Other possible examples of different imaging characteristics are discussed herein.

With regard to the non-metrology, trend-only based data augmentation by any of the operations described above related to FIGS. 9-11, the loss function is configured to cause the machine learning model to fit the relative relationships between measurements (e.g., values) of imaging characteristics predicted by the physical model, rather than the absolute values of the imaging characteristics themselves. This may also reinforce and/or otherwise cause the machine learning model to ensure predictions conform to the physical trend. In this type of training data generation (augmentation), there may be no available previously determined measurements, but a certain physical trend is known to exist based on a physical model and/or physics knowledge. The loss function is configured to cause the machine learning model to be trained to follow that physical trend, rather than any actual absolute measurements. In these embodiments (noting that this is just one example of a loss function), the following standard deviation based loss function can be applied to drive machine learning model training convergence:

$$\\ STD = \sqrt{\frac{\sum {( {Error}_{i} - {Error}_{ave} )}^{2}}{N}}$$

where STD is an error standard deviation, Errorᵢ is model error relative to a physical model prediction (value), Error_{average} is an average of all errors, and N is a sample number. This loss function tries to minimize model error (relative to physical model measurements (values)) standard deviation, without requiring average model errors to be zero. It can effectively drive the machine learning model to learn the physical trend, rather than any actual absolute accuracy of imaging characteristic measurements.

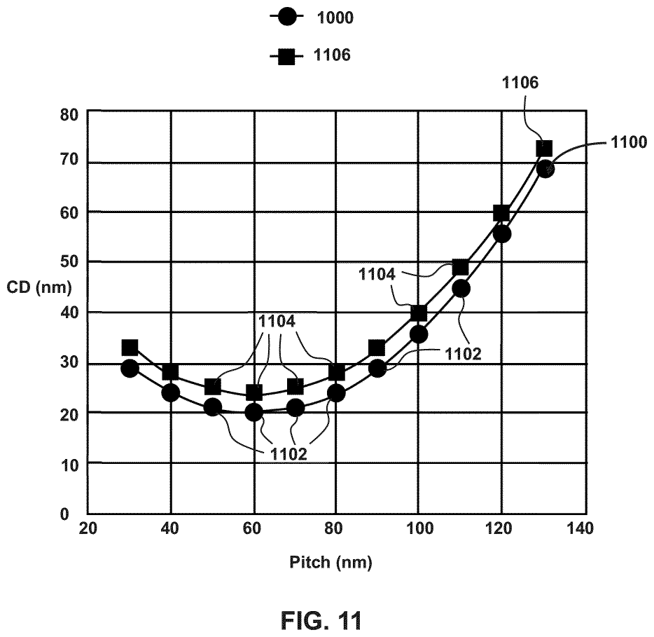

By way of a non-limiting example, FIG. 11 illustrates a physical trend 1100 defined by imaging characteristic (critical dimension—CD—in this example) measurements 1102 predicted by a physical model compared to predicted imaging characteristic measurements 1104 from a machine learning model that follow a similar trend 1106, according to an embodiment. FIG. 11 illustrates how, even though measurements 1102 do not match measurements 1104, trend 1106 defined by measurements 1104 closely follows trend 1100. The loss function described above is configured to cause the machine learning model to fit the relative relationships between measurements 1102 of an imaging characteristic (CD in this example) predicted by the physical model, rather than the absolute measurements (values) of the imaging characteristics themselves.

In some embodiments, the augmented data (described above) is associated with a normalized version of the standard deviation based loss function described above. The normalized standard deviation based loss function may be normalized based on a range of all critical dimensions (CD) in data (e.g., first data from a first patterning process and/or second data from a second and/or other patterning processes as described above) associated with a physical trend. For example, the following normalized standard deviation based loss function (noting again that this is just one other example of a loss function) can be applied to drive machine learning model training convergence:

$$\\ {STD}_{norm} = \sqrt{\frac{\sum {( {Error}_{i} - {Error}_{ave} )}^{2}}{N {CD}_{range}}}$$

where STDₙₒᵣₘ is a normalized error standard deviation, Error; is model error relative to a physical model prediction (value), Errorₐᵥₑ is an average of all errors, N is a sample number, and CD_{range} is the range of all CD's for a physical trend. This loss function may be configured to (further) normalize relative model errors based on the CD range. It can effectively drive the machine learning model to only learn a normalized trend. It can be used when a tuning process involves a scaled change in the critical dimension, for example, changing the time of an etch step that has a strong loading effect.

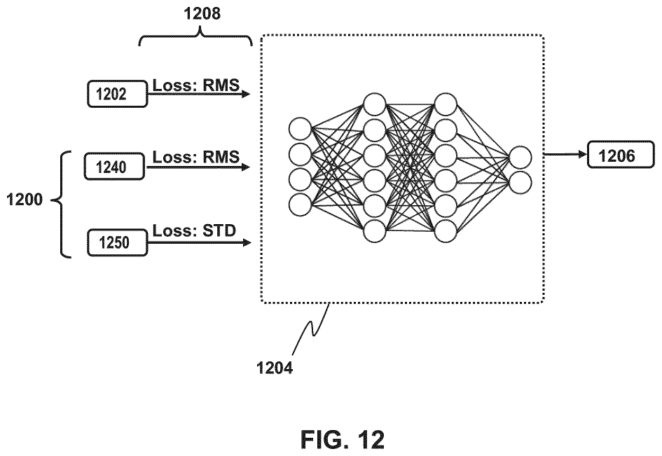

As a brief summary, FIG. 12 (which is similar to FIG. 4) illustrates data 1200 used to augment data 1202 (e.g., previously determined imaging characteristic measurements made on actual substrates) used to train 1204 a machine learning model (e.g., a neural network comprising multiple layers in this example) 1206. Augmented data 1200 is determined based on physical trends associated with a set of patterns on a substrate and/or process variation resulting from a patterning process. As shown in FIG. 12, augmented data 1200 includes data 1240 and 1250 generated by the metrology data based augmentation; and the non-metrology, trend-only based data augmentation described herein, respectively. Augmented data 1200 is provided together with data 1202 (in this example) as input 1208 to train 404 machine learning model 1206. Machine learning model 1206 is trained 1204 to predict the one or more imaging characteristics according to a physical trend based on a loss function. Training machine learning model 1206 to predict the one or more imaging characteristics according to the physical trend based on a loss function may reinforce and/or otherwise cause machine learning model 1206 to ensure predictions conform to the physical trend. As shown in FIG. 12, the RMS based loss function described above is used with data 1202 and/or data 1240, while the standard deviation based loss function described above is used with data 1250. Note the standard deviation based loss function STD shown in FIG. 12 may include the standard deviation based (e.g., STD) and/or the normalized standard deviation based loss function (e.g., STDₙₒᵣₘ) described above, for example. Augmented data 1200 is configured to enhance the accuracy of predictions from machine learning model 1206 with respect to the physical trends relative to prior models.

Returning to FIG. 3, once trained, the machine learning model is configured to predict the one or more imaging characteristics with respect to variation in a pattern on a substrate resulting from the patterning process. The machine learning model may be configured to predict an impact one or more pattern and/or patterning process parameters may have on the one or more imaging characteristics. A machine learning model may be applied in an after development inspection (ADI), predicting an after etch inspection (AEI), optical proximity correction (OPC), hotspot or defect prediction, source mask optimization (SMO), and/or other operations in a semiconductor lithography process, an etching process, and/or other operations. As described above, providing the augmented training data to the machine learning model can significantly increase machine learning model prediction accuracy (e.g., by reducing overfitting), without incurring additional metrology and/or other processing costs, among other advantages.

At an operation 308, output from the machine learning model is provided for various downstream applications. In some embodiments, operation 308 includes providing the output from the machine learning model for adjustment and/or optimization of the pattern, the patterning process, and/or for other purposes. For example, in some embodiments, output from the machine learning model is configured to be provided to a cost function to facilitate determination of costs associated with individual patterning process variables. Providing may include electronically sending, uploading, and/or otherwise inputting predictions from the machine learning model into the cost function. In some embodiments, this may be integrally programmed with the instructions that cause others of operations 302-308 (e.g., such that no “providing” is required, and instead data simply flows directly to the cost function.

Adjustments to a pattern, a patterning process (e.g., a semiconductor manufacturing process) may be made based on the output from the machine learning model, the cost function, and/or based on other information. Adjustments may including changing one or more patterning process parameters, for example. Adjustments may include pattern parameter changes (e.g., sizes, locations, and/or other design variables), and/or any adjustable parameter such as an adjustable parameter of the etching system, the source, the patterning device, the projection optics, dose, focus, etc. Parameters may be automatically or otherwise electronically adjusted by a processor (e.g., a computer controller), modulated manually by a user, or adjusted in other ways. In some embodiments, parameter adjustments may be determined (e.g., an amount a given parameter should be changed), and the parameters may be adjusted from prior parameter set points to new parameter set points, for example.

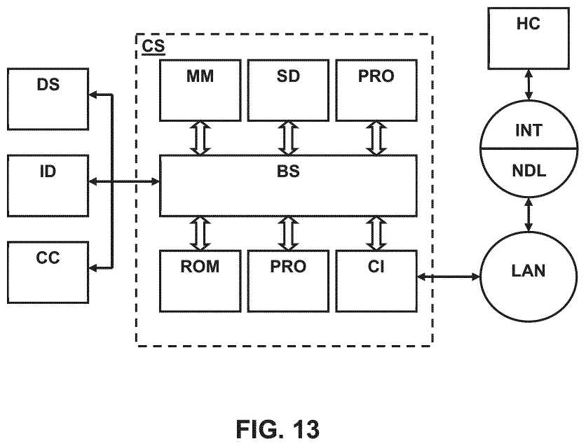

FIG. 13 is a diagram of an example computer system CS that may be used for one or more of the operations described herein. Computer system CS includes a bus BS or other communication mechanism for communicating information, and a processor PRO (or multiple processors) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” or “machine readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic, or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic, or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

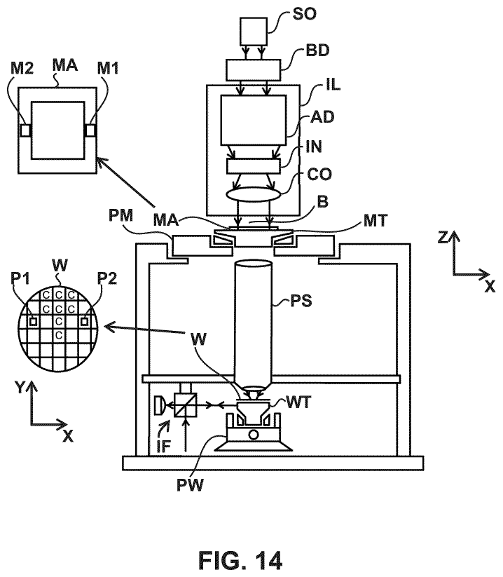

FIG. 14 is a schematic diagram of a lithographic projection apparatus, according to an embodiment. The lithographic projection apparatus can include an illumination system IL, a first object table MT, a second object table WT, and a projection system PS. Illumination system IL, can condition a beam B of radiation. In this example, the illumination system also comprises a radiation source SO. First object table (e.g., a patterning device table) MT can be provided with a patterning device holder to hold a patterning device MA (e.g., a reticle), and connected to a first positioner to accurately position the patterning device with respect to item PS. Second object table (e.g., a substrate table) WT can be provided with a substrate holder to hold a substrate W (e.g., a resist-coated silicon wafer), and connected to a second positioner to accurately position the substrate with respect to item PS. Projection system (e.g., which includes a lens) PS (e.g., a refractive, catoptric or catadioptric optical system) can image an irradiated portion of the patterning device MA onto a target portion C (e.g., comprising one or more dies) of the substrate W. Patterning device MA and substrate W may be aligned using patterning device alignment marks M1, M2 and substrate alignment marks P1, P2, for example.

As depicted, the apparatus can be of a transmissive type (i.e., has a transmissive patterning device). However, in general, it may also be of a reflective type, for example (with a reflective patterning device). The apparatus may employ a different kind of patterning device for a classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander, or beam delivery system BD (comprising directing mirrors, the beam expander, etc.). for example. The illuminator IL may comprise adjusting means AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus. The radiation beam that it produces may be led into the apparatus (e.g., with the aid of suitable directing mirrors), for example. This latter scenario can be the case when source SO is an excimer laser (e.g., based on KrF, ArF or F2 lasing), for example.

The beam B can subsequently intercept patterning device MA, which is held on a patterning device table MT. Having traversed patterning device MA, the beam B can pass through the lens PL, which focuses beam B onto target portion C of substrate W. With the aid of the second positioning means (and interferometric measuring means IF), the substrate table WT can be moved accurately, e.g. to position different target portions C in the path of beam B. Similarly, the first positioning means can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool), patterning device table MT may be connected to a short stroke actuator, or may be fixed.

The depicted tool can be used in two different modes, step mode and scan mode. In step mode, patterning device table MT is kept essentially stationary, and an entire patterning device image is projected in one operation (i.e., a single “flash”) onto a target portion C. Substrate table WT can be shifted in the x and/or y directions so that a different target portion C can be irradiated by beam B. In scan mode, essentially the same scenario applies, except that a given target portion C is not exposed in a single “flash.” Instead, patterning device table MT is movable in a given direction (e.g., the “scan direction”, or the “y” direction) with a speed v, so that projection beam B is caused to scan over a patterning device image. Concurrently, substrate table WT is simultaneously moved in the same or opposite direction at a speed V=Mv, in which M is the magnification of the lens (typically, M=¼ or ⅕). In this manner, a relatively large target portion C can be exposed, without having to compromise on resolution.

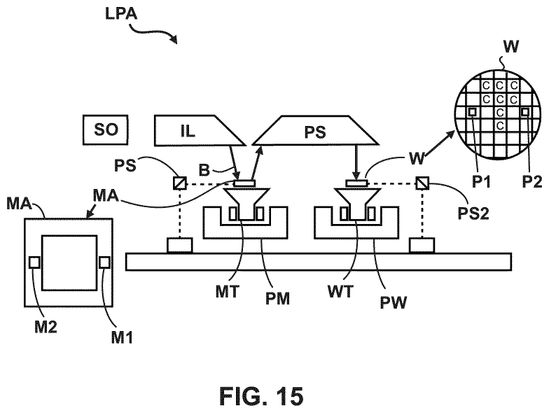

FIG. 15 is a schematic diagram of another lithographic projection apparatus (LPA) that may be used for, and/or facilitating one or more of the operations described herein. LPA can include source collector module SO, illumination system (illuminator) IL configured to condition a radiation beam B (e.g. EUV radiation), support structure MT, substrate table WT, and projection system PS. Support structure (e.g. a patterning device table) MT can be constructed to support a patterning device (e.g. a mask or a reticle) MA and connected to a first positioner PM configured to accurately position the patterning device. Substrate table (e.g. a wafer table) WT can be constructed to hold a substrate (e.g. a resist coated wafer) W and connected to a second positioner PW configured to accurately position the substrate. Projection system (e.g. a reflective projection system) PS can be configured to project a pattern imparted to the radiation beam B by patterning device MA onto a target portion C (e.g. comprising one or more dies) of the substrate W.

As shown in this example, LPA can be of a reflective type (e.g. employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultra violet radiation beam from source collector module SO. Methods to produce EUV radiation include, but are not necessarily limited to, converting a material into a plasma state that has at least one element, e.g., xenon, lithium, or tin, with one or more emission lines in the EUV range. In one such method, often termed laser produced plasma (“LPP”), the plasma can be produced by irradiating a fuel, such as a droplet, stream or cluster of material having the line-emitting element, with a laser beam. Source collector module SO may be part of an EUV radiation system including a laser (not shown in FIG. 15), for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation. In this example, the laser may not be considered to form part of the lithographic apparatus and the radiation beam can be passed from the laser to the source collector module with the aid of a beam delivery system comprising, for example, suitable directing mirrors and/or a beam expander. In other examples, the source may be an integral part of the source collector module, for example when the source is a discharge produced plasma EUV generator, often termed a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder, or capacitive sensor), the substrate table WT can be moved accurately (e.g. to position different target portions C in the path of radiation beam B). Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus LPA could be used in at least one of the following modes, step mode, scan mode, and stationary mode. In step mode, the support structure (e.g. patterning device table) MT and the substrate table WT are kept essentially stationary, while an entire pattern imparted to the radiation beam is projected onto a target portion C at one time (e.g., a single static exposure). The substrate table WT is then shifted in the X and/or Y direction so that a different target portion C can be exposed. In scan mode, the support structure (e.g. patterning device table) MT and the substrate table WT are scanned synchronously while a pattern imparted to the radiation beam is projected onto target portion C (i.e. a single dynamic exposure). The velocity and direction of substrate table WT relative to the support structure (e.g. patterning device table) MT may be determined by the (de)magnification and image reversal characteristics of the projection system PS. In stationary mode, the support structure (e.g. patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

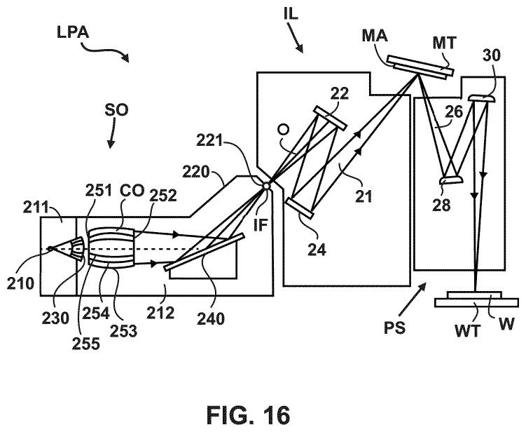

FIG. 16 is a detailed view of the lithographic projection apparatus shown in FIG. 15. As shown in FIG. 16, the LPA can include the source collector module SO, the illumination system IL, and the projection system PS. The source collector module SO is configured such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the hot plasma 210 is created to emit radiation in the EUV range of the electromagnetic spectrum. The hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier trap 230 (described below) also includes a channel structure. The collector chamber 211 may include a radiation collector CO which may be a grazing incidence collector.

Radiation collector CO has an upstream radiation collector side 251 and a downstream radiation collector side 252. Radiation that traverses collector CO can be reflected off a grating spectral filter 240 to be focused on a virtual source point IF along the optical axis indicated by the line “O”. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently, the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the radiation beam 21 at the patterning device MA, held by the support structure MT, a patterned beam 26 is formed and the patterned beam 26 is imaged by the projection system PS via reflective elements 28, 30 onto a substrate W held by the substrate table WT. More elements than shown may generally be present in illumination optics unit IL and projection system PS. The grating spectral filter 240 may optionally be present, depending upon the type of lithographic apparatus, for example. Further, there may be more mirrors present than those shown in the figures, for example there may be 1-6 additional reflective elements present in the projection system PS than shown in FIG. 16.

Collector optic CO, as illustrated in FIG. 16, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

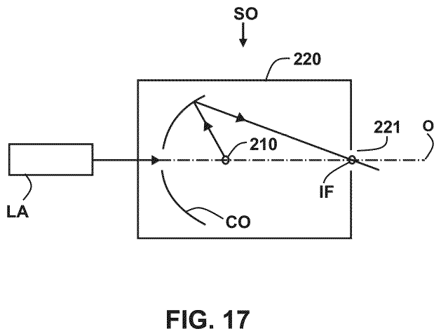

FIG. 17 is a detailed view of source collector module SO of the lithographic projection apparatus LPA (shown in previous figures). Source collector module SO may be part of an LPA radiation system. A laser LA can be arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

Embodiments of the present disclosure can be further described by the following clauses.

1. A non-transitory computer readable medium having instructions thereon, the instructions when executed by a computer causing the computer to perform a method comprising:
determining a physical trend of one or more imaging characteristics with respect to pattern variation on a substrate resulting from a patterning process, the physical trend determined based on first data for a first set of patterns and/or the patterning process; and
generating augmented data based on the physical trend, the augmented data comprising second data that conforms to the physical trend and is derived based on the first data, the augmented data derived for a second set of patterns that are different from the first set; wherein
   the augmented data is configured to be provided as input to a machine learning model to train the machine learning model to predict the one or more imaging characteristics according to the physical trend.

2. The medium of clause 1, wherein the physical trend is associated with pattern design variation on the substrate and/or patterning process variation.

3. The medium of clause 1 or 2, wherein the augmented data is provided as input to the machine learning model to train the machine learning model to conform predictions of the one or more imaging characteristics according to the physical trend.

4. The medium of any of clauses 1-3, wherein:
the first data comprises previously determined measurements of the pattern on the substrate, and/or information indicative of a physical behavior of the pattern on the substrate resulting from the patterning process; and
the augmented data is new relative to the previously determined measurements and/or the information indicative of the physical behavior of the pattern on the substrate, but still conforms to the physical trend.

5. The medium of any of clauses 1-4, wherein the method further comprises providing the augmented data to the machine learning model to train the machine learning model to predict the one or more imaging characteristics according to the physical trend.

6. The medium of any of clauses 1-5, wherein the one or more imaging characteristics comprise a critical dimension, an edge location, a curvature, a pitch, a symmetry, or a rotation.

7. The medium of any of clauses 1-6, wherein the patterning process comprises a lithography process and/or an etching process.

8. The medium of any of clauses 1-7, wherein generating the augmented data is based on measurements of the one or more imaging characteristics included in the first data, the first data comprising previously determined data for the first set of patterns and/or the patterning process that at least partially defines the physical trend.

9. The medium of clause 8, wherein generating the augmented data comprises mathematically interpolating between the measurements of a given imaging characteristic to determine additional measurements of the given imaging characteristic.

10. The medium of clause 8, wherein generating the augmented data comprises calibrating a physical model associated with the physical trend using the measurements, and using the calibrated physical model to predict additional measurements that conform to the physical trend.

11. The medium of clause 10, wherein the physical model comprises a multi-dimensional algorithm having terms that collectively simulate the physical trend and/or the patterning process.

12. The medium of clause 10 or 11, wherein generating the augmented data further comprises calibrating, using the measurements, a residue model configured to compensate for error in the predicted additional measurements, and generating the augmented data using the physical model and the residue model,
wherein the residue model comprises a purely mathematical model calibrated by fitting errors in predictions from the physical model to the measurements.

13. The medium of clause 8, wherein generating the augmented data is based on the measurements and symmetry in the pattern resulting from the patterning process.

14. The medium of any of clauses 1-13, wherein generating the augmented data comprises determining the physical trend based on outputs from a trained physical model, the trend described by relative relationships between values of imaging characteristics predicted by the physical model, rather than absolute values of the imaging characteristics themselves.

15. The medium of clause 14, wherein the physical trend comprises a symmetry trend, an orientation trend, a focus trend, a dose trend, a through pitch trend, a linearity trend, and/or a through critical dimension trend.

16. The medium of clause 14 or 15, wherein the machine learning model is trained to predict the one or more imaging characteristics according to the physical trend based on a loss function configured to cause the machine learning model to fit the relative relationships between values of imaging characteristics predicted by the physical model, rather than the absolute values of the imaging characteristics themselves.

17. The medium of any of clauses 1-16, wherein the physical trend is known based on prior pattern variation on the substrate and/or prior patterning process variation.

18. The medium of any of clauses 1-17, wherein output from the machine learning model is configured to be provided to a cost function to facilitate determination of costs associated with individual patterning process variables.

19. The medium of any of clauses 1-3, wherein the first data comprises previously determined measurements of a first pattern or set of patterns on a first substrate produced by a first patterning process, and wherein the physical trend is determined and/or otherwise obtained by (1) extracting and/or categorizing measurements of the first pattern or set of patterns on the first substrate associated with the physical trend, and/or (2) fitting a physical model to the measurements of the first pattern or set of patterns.

20. The medium of clause 19, wherein the first patterning process comprises one or more semiconductor manufacturing patterning processes that have similar and comparable process conditions with a second patterning process.

21. The medium of clause 20, wherein the second patterning process comprises a target patterning process which is simulated and/or for which a model is constructed.

22. The medium of any of clauses 19-21, wherein the augmented data comprises new data generated based on the physical trend and/or by the physical model, and/or a subset of the previously determined measurements from the first data that conforms to the physical trend.

23. The medium of clause 22, wherein the augmented data is combinable with second measurements from a second pattern or set of patterns on a second substrate produced by the second patterning process.

24. The medium of clause 23, wherein the subset of the previously determined measurements from the first data that conforms to the physical trend comprises data associated with a previous mask when the first patterning process and the second patterning process are similar.

25. The medium of any of clauses 23 or 24, wherein the subset of the previously determined measurements from the first data that conforms to the physical trend comprises data associated with different locations on a current mask when the second patterning process is adjusted relative to the first patterning process.

26. The medium of any of clauses 23-25, wherein the second data comprises less second measurements from the second pattern on the second substrate produced by the second patterning process compared to a quantity for the second measurements if no augmented data is used, the less second measurements being combinable with the new data generated based on the physical trend and/or by the physical model, and/or the subset of the previously determined measurements from the first data that conforms to the physical trend.

27. The medium of any of clauses 19-26, wherein a total amount of the augmented data has a same or increased data density relative to the previously determined measurements of the first pattern on the first substrate produced by the first patterning process.

28. The medium of any of clauses 1-27, wherein the augmented data is associated with a normalized standard deviation based loss function.

29. The medium of clause 28, wherein the augmented data, the second measurement data, and/or the normalized standard deviation based loss function are used to train the machine learning model.

30. The medium of clauses 28 or 29, wherein the normalized standard deviation based loss function is normalized based on a range of all critical dimensions in the first data associated with the physical trend.

31. A method for generating augmented data, the method comprising:
determining a physical trend of one or more imaging characteristics with respect to pattern variation on a substrate resulting from a patterning process, the physical trend determined based on first data for a first set of patterns and/or the patterning process; and
generating the augmented data based on the physical trend, the augmented data comprising second data that conforms to the physical trend and is derived based on the first data, the augmented data derived for a second set of patterns that are different from the first set; wherein
   the augmented data is configured to be provided as input to a machine learning model to train the machine learning model to predict the one or more imaging characteristics according to the physical trend.

32. The method of clause 31, wherein the physical trend is associated with pattern design variation on the substrate and/or patterning process variation.

33. The method of clause 31 or 32, wherein the method further comprises providing the augmented data as input to the machine learning model to train the machine learning model to conform predictions of the one or more imaging characteristics according to the physical trend.

34. The method of any of clauses 31-33, wherein:
the first data comprises previously determined measurements of the pattern on the substrate, and/or information indicative of a physical behavior of the pattern on the substrate resulting from the patterning process; and
the augmented data is new relative to the previously determined measurements and/or the information indicative of the physical behavior of the pattern on the substrate, but still conforms to the physical trend.

35. The method of any of clauses 31-34, wherein the method further comprises providing the augmented data to the machine learning model to train the machine learning model to predict the one or more imaging characteristics according to the physical trend.

36. The method of any of clauses 31-35, wherein the one or more imaging characteristics comprise a critical dimension, an edge location, a curvature, a pitch, a symmetry, or a rotation.

37. The method of any of clauses 31-36, wherein the patterning process comprises a lithography process and/or an etching process.

38. The method of any of clauses 31-37, wherein generating the augmented data is based on measurements of the one or more imaging characteristics included in the first data, the first data comprising previously determined data for the first set of patterns and/or the patterning process that at least partially defines the physical trend.

39. The method of clause 38, wherein generating the augmented data comprises mathematically interpolating between the measurements of a given imaging characteristic to determine additional measurements of the given imaging characteristic.

40. The method of clause 38, wherein generating the augmented data comprises calibrating a physical model associated with the physical trend using the measurements, and using the calibrated physical model to predict additional measurements that conform to the physical trend.

41. The method of clause 40, wherein the physical model comprises a multi-dimensional algorithm having terms that collectively simulate the physical trend and/or the patterning process.

42. The method of clause 40 or 41, wherein generating the augmented data further comprises calibrating, using the measurements, a residue model configured to compensate for error in the predicted additional measurements, and generating the augmented data using the physical model and the residue model,
wherein the residue model comprises a purely mathematical model calibrated by fitting errors in predictions from the physical model to the measurements.

43. The method of clause 38, wherein generating the augmented data is based on the measurements and symmetry in the pattern resulting from the patterning process.

44. The method of any of clauses 31-43, wherein generating the augmented data comprises determining the physical trend based on outputs from a trained physical model, the trend described by relative relationships between values of imaging characteristics predicted by the physical model, rather than absolute values of the imaging characteristics themselves.

45. The method of clause 44, wherein the physical trend comprises a symmetry trend, an orientation trend, a focus trend, a dose trend, a through pitch trend, a linearity trend, and/or a through critical dimension trend.

46. The method of clause 44 or 45, wherein the machine learning model is trained to predict the one or more imaging characteristics according to the physical trend based on a loss function configured to cause the machine learning model to fit the relative relationships between values of imaging characteristics predicted by the physical model, rather than the absolute values of the imaging characteristics themselves.

47. The method of any of clauses 31-46, wherein the physical trend is known based on prior pattern variation on the substrate and/or prior patterning process variation.

48. The method of any of clauses 31-47, wherein output from the machine learning model is configured to be provided to a cost function to facilitate determination of costs associated with individual patterning process variables.

49. The method of any of clauses 31-33, wherein the first data comprises previously determined measurements of a first pattern or set of patterns on a first substrate produced by a first patterning process, and wherein the physical trend is determined and/or otherwise obtained by (1) extracting and/or categorizing measurements of the first pattern or set of patterns on the first substrate associated with the physical trend, and/or (2) fitting a physical model to the measurements of the first pattern or set of patterns.

50. The method of clause 49, wherein the first patterning process comprises one or more semiconductor manufacturing patterning processes that have similar and comparable process conditions with a second patterning process.

51. The method of clause 50, wherein the second patterning process comprises a target patterning process which is simulated and/or for which a model is constructed.

52. The method of any of clauses 49-51, wherein the augmented data comprises new data generated based on the physical trend and/or by the physical model, and/or a subset of the previously determined measurements from the first data that conforms to the physical trend.

53. The method of clause 52, wherein the augmented data is combinable with second measurements from a second pattern or set of patterns on a second substrate produced by the second patterning process.

54. The method of clause 53, wherein the subset of the previously determined measurements from the first data that conforms to the physical trend comprises data associated with a previous mask when the first patterning process and the second patterning process are similar.

55. The method of any of clauses 53 or 54, wherein the subset of the previously determined measurements from the first data that conforms to the physical trend comprises data associated with different locations on a current mask when the second patterning process is adjusted relative to the first patterning process.

56. The method of any of clauses 53-55, wherein the second data comprises less second measurements from the second pattern on the second substrate produced by the second patterning process compared to a quantity for the second measurements if no augmented data is used, the less second measurements being combinable with the new data generated based on the physical trend and/or by the physical model, and/or the subset of the previously determined measurements from the first data that conforms to the physical trend.

57. The method of any of clauses 49-56, wherein a total amount of the augmented data has a same or increased data density relative to the previously determined measurements of the first pattern on the first substrate produced by the first patterning process.

58. The method of any of clauses 31-57, wherein the augmented data is associated with a normalized standard deviation based loss function.

59. The method of clause 58, wherein the augmented data, the second measurement data, and/or the normalized standard deviation based loss function are used to train the machine learning model.

60. The method of clauses 58 or 59, wherein the normalized standard deviation based loss function is normalized based on a range of all critical dimensions in the first data associated with the physical trend.

61. A system for generating augmented data comprising one or more processors configured by machine readable instructions to:
determine a physical trend of one or more imaging characteristics with respect to pattern variation on a substrate resulting from a patterning process, the physical trend determined based on first data for a first set of patterns and/or the patterning process; and
generate the augmented data based on the physical trend, the augmented data comprising second data that conforms to the physical trend and is derived based on the first data, the augmented data derived for a second set of patterns that are different from the first set; wherein
   the augmented data is configured to be provided as input to a machine learning model to train the machine learning model to predict the one or more imaging characteristics according to the physical trend.

62. The system of clause 61, wherein the physical trend is associated with pattern design variation on the substrate and/or patterning process variation.

63. The system of clause 61 or 62, wherein the one or more processors are further configured to provide the augmented data as input to the machine learning model to train the machine learning model to conform predictions of the one or more imaging characteristics according to the physical trend.

64. The system of any of clauses 61-63, wherein:
the first data comprises previously determined measurements of the pattern on the substrate, and/or information indicative of a physical behavior of the pattern on the substrate resulting from the patterning process; and
the augmented data is new relative to the previously determined measurements and/or the information indicative of the physical behavior of the pattern on the substrate, but still conforms to the physical trend.

65. The system of any of clauses 61-64, wherein the one or more processors are further configured to provide the augmented data to the machine learning model to train the machine learning model to predict the one or more imaging characteristics according to the physical trend.

66. The system of any of clauses 61-65, wherein the one or more imaging characteristics comprise a critical dimension, an edge location, a curvature, a pitch, a symmetry, or a rotation.

67. The system of any of clauses 61-66, wherein the patterning process comprises a lithography process and/or an etching process.

68. The system of any of clauses 61-67, wherein generating the augmented data is based on measurements of the one or more imaging characteristics included in the first data, the first data comprising previously determined data for the first set of patterns and/or the patterning process that at least partially defines the physical trend.

69. The system of clause 68, wherein generating the augmented data comprises mathematically interpolating between the measurements of a given imaging characteristic to determine additional measurements of the given imaging characteristic.

70. The system of clause 68, wherein generating the augmented data comprises calibrating a physical model associated with the physical trend using the measurements, and using the calibrated physical model to predict additional measurements that conform to the physical trend.

71. The system of clause 70, wherein the physical model comprises a multi-dimensional algorithm having terms that collectively simulate the physical trend and/or the patterning process.

72. The system of clause 70 or 71, wherein generating the augmented data further comprises calibrating, using the measurements, a residue model configured to compensate for error in the predicted additional measurements, and generating the augmented data using the physical model and the residue model,
wherein the residue model comprises a purely mathematical model calibrated by fitting errors in predictions from the physical model to the measurements.

73. The system of clause 68, wherein generating the augmented data is based on the measurements and symmetry in the pattern resulting from the patterning process.

74. The system of any of clauses 71-73, wherein generating the augmented data comprises determining the physical trend based on outputs from a trained physical model, the trend described by relative relationships between values of imaging characteristics predicted by the physical model, rather than absolute values of the imaging characteristics themselves.

75. The system of clause 74, wherein the physical trend comprises a symmetry trend, an orientation trend, a focus trend, a dose trend, a through pitch trend, a linearity trend, and/or a through critical dimension trend.

76. The system of clause 74 or 75, wherein the machine learning model is trained to predict the one or more imaging characteristics according to the physical trend based on a loss function configured to cause the machine learning model to fit the relative relationships between values of imaging characteristics predicted by the physical model, rather than the absolute values of the imaging characteristics themselves.

77. The system of any of clauses 61-76, wherein the physical trend is known based on prior pattern variation on the substrate and/or prior patterning process variation.

78. The system of any of clauses 61-77, wherein output from the machine learning model is configured to be provided to a cost function to facilitate determination of costs associated with individual patterning process variables.

79. The system of any of clauses 61-63, wherein the first data comprises previously determined measurements of a first pattern or set of patterns on a first substrate produced by a first patterning process, and wherein the physical trend is determined and/or otherwise obtained by (1) extracting and/or categorizing measurements of the first pattern or set of patterns on the first substrate associated with the physical trend, and/or (2) fitting a physical model to the measurements of the first pattern or set of patterns.

80. The system of clause 79, wherein the first patterning process comprises one or more semiconductor manufacturing patterning processes that have similar and comparable process conditions with a second patterning process.

81. The system of clause 80, wherein the second patterning process comprises a target patterning process which is simulated and/or for which a model is constructed.

82. The system of any of clauses 79-81, wherein the augmented data comprises new data generated based on the physical trend and/or by the physical model, and/or a subset of the previously determined measurements from the first data that conforms to the physical trend.

83. The system of clause 82, wherein the augmented data is combinable with second measurements from a second pattern or set of patterns on a second substrate produced by the second patterning process.

84. The system of clause 83, wherein the subset of the previously determined measurements from the first data that conforms to the physical trend comprises data associated with a previous mask when the first patterning process and the second patterning process are similar.

85. The system of any of clauses 83 or 84, wherein the subset of the previously determined measurements from the first data that conforms to the physical trend comprises data associated with different locations on a current mask when the second patterning process is adjusted relative to the first patterning process.

86. The system of any of clauses 83-85, wherein the second data comprises less second measurements from the second pattern on the second substrate produced by the second patterning process compared to a quantity for the second measurements if not augmented data is used, the less second measurements being combinable with the new data generated based on the physical trend and/or by the physical model, and/or the subset of the previously determined measurements from the first data that conforms to the physical trend.

87. The system of any of clauses 79-86, wherein a total amount of the augmented data has a same or increased data density relative to the previously determined measurements of the first pattern on the first substrate produced by the first patterning process.

88. The system of any of clauses 61-87, wherein the augmented data is associated with a normalized standard deviation based loss function.

89. The system of clause 88, wherein the augmented data, the second measurement data, and/or the normalized standard deviation based loss function are used to train the machine learning model.

90. The system of clauses 88 or 89, wherein the normalized standard deviation based loss function is normalized based on a range of all critical dimensions in the first data associated with the physical trend.

91. A non-transitory computer readable medium having instructions thereon, the instructions when executed by a computer, causing the computer to train a machine learning model with augmented training data determined based on physical trends associated with a set of patterns on a wafer and/or process variation resulting from a lithography process, the augmented training data configured to enhance a prediction accuracy of a machine learning model with respect to the physical trends relative to prior models, the instructions causing operations comprising:
determining a physical trend of one or more imaging characteristics with respect to variation in the set of patterns on the wafer resulting from the lithography process, the physical trend determined based on first data for a first set of patterns and/or the lithography process;
generating the augmented training data based on the physical trend, the augmented training data comprising second data that conforms to the physical trend and is derived based on the first data, the augmented training data derived for a second set of patterns that are different from the first set; and
providing the augmented training data as input to a machine learning model to train the machine learning model to predict the one or more imaging characteristics according to the physical trend.

92. The medium of clause 91, wherein the one or more imaging characteristics comprise a critical dimension, an edge location, a curvature, a pitch, a symmetry, or a rotation.

93. The medium of clause 91, wherein generating the augmented training data is based on measurements of imaging characteristics included in the first data; and wherein
(1) generating the augmented training data comprises mathematically interpolating between the measurements of a given imaging characteristic to determine additional measurements of the given imaging characteristic;
(2) generating the augmented training data comprises calibrating a physical model associated with the physical trend using the measurements, and using the calibrated physical model to predict additional measurements;
(3) generating the augmented training data further comprises calibrating, using the measurements, a residue model configured to compensate for error in the predicted additional measurements, and generating the augmented training data using the physical model and the residue model,
wherein the residue model comprises a purely mathematical model calibrated by fitting errors in predictions from the physical model to measurements.
   or
(4) generating the augmented training data is based on the measurements and symmetry in the pattern resulting from the lithography process.

94. The medium of clause 91, wherein generating the augmented training data comprises determining the physical trend based on outputs from a trained physical model, the trend described by relative relationships between values of imaging characteristics predicted by the physical model, rather than absolute values of the imaging characteristics themselves.

The concepts disclosed herein may simulate or mathematically model any generic imaging, etching, polishing, inspection, etc. system for sub wavelength features, and may be useful with emerging imaging technologies capable of producing increasingly shorter wavelengths. Emerging technologies include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

While the concepts disclosed herein may be used for manufacturing with a substrate such as a silicon wafer, it shall be understood that the disclosed concepts may be used with any type of manufacturing system (e.g., those used for manufacturing on substrates other than silicon wafers).

In addition, the combination and sub-combinations of disclosed elements may comprise separate embodiments. For example, one or more of the operations described above may be included in separate embodiments, or they may be included together in the same embodiment.

The descriptions above are intended to be illustrative, not limiting. Thus, it will be apparent to one skilled in the art that modifications may be made as described without departing from the scope of the claims set out below.

1. A non-transitory computer readable medium having instructions therein or thereon, the instructions, when executed by a computer system, configured to cause the computer system to at least:
determine a physical trend of one or more imaging characteristics with respect to pattern variation on a substrate resulting from a patterning process, the physical trend determined based on first data for a first set of patterns and/or the patterning process; and
generate augmented data based on the physical trend, the augmented data comprising second data that conforms to the physical trend and is derived based on the first data, the augmented data derived for a second set of patterns that are different from the first set,
wherein the augmented data is configured to be provided as input to a machine learning model to train the machine learning model to predict the one or more imaging characteristics according to the physical trend.

2. The medium of claim 1, wherein the physical trend is associated with pattern design variation on the substrate and/or patterning process variation.

3. The medium of claim 1, wherein the instructions are further configured to cause the computer system to provide the augmented data as input to the machine learning model to train the machine learning model to conform predictions of the one or more imaging characteristics according to the physical trend.

4. The medium of claim 1, wherein:
the first data comprises previously determined measurements of a pattern on the substrate, and/or information indicative of a physical behavior of a pattern on the substrate resulting from the patterning process; and
the augmented data is new relative to the previously determined measurements and/or the information indicative of the physical behavior, but still conforms to the physical trend.

5. The medium of claim 1, wherein the one or more imaging characteristics comprise a critical dimension, an edge location, a curvature, a pitch, a symmetry, or a rotation.

6. The medium of claim 1, wherein the instructions configured to cause the computer system to generate the augmented data are further configured to cause the computer system to generate the augmented data based on measurements of the one or more imaging characteristics included in the first data, the first data comprising previously determined data for the first set of patterns and/or the patterning process that at least partially defines the physical trend.

7. The medium of claim 6, wherein the instructions configured to cause the computer system to generate the augmented data are further configured to cause the computer system to mathematically interpolate between the measurements of a given imaging characteristic to determine additional measurements of the given imaging characteristic.

8. The medium of claim 6, wherein the instructions configured to cause the computer system to generate the augmented data are further configured to cause the computer system to calibrate a physical model associated with the physical trend using the measurements, and use the calibrated physical model to predict additional measurements that conform to the physical trend.

9. The medium of claim 8, wherein the physical model comprises a multi-dimensional algorithm having terms that collectively simulate the physical trend and/or the patterning process.

10. The medium of claim 8, wherein the instructions configured to cause the computer system to generate the augmented data are further configured to cause the computer system to calibrate, using the measurements, a residue model configured to compensate for error in the predicted additional measurements, and generate the augmented data using the physical model and the residue model, wherein the residue model comprises a purely mathematical model calibrated by fitting errors in predictions from the physical model to the measurements.

11. The medium of claim 6, wherein the instructions configured to cause the computer system to generate the augmented data are further configured to cause the computer system to generate the augmented data based on the measurements and symmetry in the pattern resulting from the patterning process.

12. The medium of claim 1, wherein the instructions configured to cause the computer system to generate the augmented data are further configured to cause the computer system to determine the physical trend based on outputs from a trained physical model, the trend described by relative relationships between values of imaging characteristics predicted by the physical model, rather than absolute values of the imaging characteristics themselves.

13. The medium of claim 1, wherein the physical trend comprises a symmetry trend, an orientation trend, a focus trend, a dose trend, a through pitch trend, a linearity trend, and/or a through critical dimension trend, and wherein the augmented data is associated with a normalized standard deviation based loss function.

14. The medium of claim 12, wherein the machine learning model is trained to predict the one or more imaging characteristics according to the physical trend based on a loss function configured to cause the machine learning model to fit the relative relationships between values of imaging characteristics predicted by the physical model, rather than the absolute values of the imaging characteristics themselves.

15. The medium of claim 1, wherein the physical trend is known based on prior pattern variation on the substrate and/or prior patterning process variation.

16. The medium of claim 1, wherein output from the machine learning model is configured to be provided to a cost function to facilitate determination of costs associated with individual patterning process variables.

17. The medium of claim 1, wherein the first data comprises previously determined measurements of a first pattern or set of patterns on a first substrate produced by a first patterning process, and wherein the physical trend is based on (1) measurements of the first pattern or set of patterns on the first substrate associated with the physical trend, and/or (2) fitting a physical model to the measurements of the first pattern or set of patterns.

18. The medium of claim 17, wherein the first patterning process comprises one or more semiconductor manufacturing patterning processes that have substantially similar process conditions with a second patterning process, and wherein the second patterning process comprises a target patterning process which is simulated and/or for which a model is constructed, wherein the augmented data comprises new data generated based on the physical trend and/or by the physical model, and/or a subset of the previously determined measurements from the first data that conforms to the physical trend.

19. The medium of claim 17, wherein the augmented data is combinable with second measurements from a second pattern or set of patterns on a second substrate produced by the second patterning process, wherein the subset of the previously determined measurements from the first data that conforms to the physical trend comprises data associated with a previous mask when the first patterning process and the second patterning process are similar.

20. The medium of claim 19, wherein the subset of the previously determined measurements from the first data that conforms to the physical trend comprises data associated with different locations on a current mask when the second patterning process is adjusted relative to the first patterning process.

21. (canceled)
